(19) United States
(12) Patent Application Publication
(10) Pub. No.: US 2023/0295412 A1
(43) Pub. Date: Sep. 21, 2023

(54) LOW CEILING TEMPERATURE HOMOPOLYMERS AS SACRIFICIAL PROTECTION LAYERS FOR ENVIRONMENTALLY SENSITIVE SUBSTRATES

(71) Applicant: Lam Research Corporation, Fremont, CA (US)

(72) Inventors: Stephen M. SIRARD, Austin, TX (US); Gregory BLACHUT, Campbell, CA (US); Ratchana LIMARY, Austin, TX (US); Diane HYMES, San Jose, CA (US); Yang PAN, Los Altos, CA (US)

(21) Appl. No.: 18/006,552

(22) PCT Filed: Jul. 23, 2021
(86) PCT No.: PCT/US2021/042978

§ 371 Date: Jan. 23, 2023

Related U.S. Application Data
(60) Provisional application No. 62/706,035, filed on Jul. 28, 2020.

(51) Int. Cl. C08L 61/18; B05D 1/00; H01L 21/56; H01L 23/31; H01L 23/29

(52) U.S. Cl. CPC C08L 61/18; B05D 1/005; H01L 21/56; H01L 23/3171; H01L 23/3178; H01L 23/293; C08L 2203/162; C08L 2203/206

(57) ABSTRACT

The present disclosure relates to a stimulus responsive polymer (SRP) that includes a homopolymer. Methods, films, and formulations employing an SRP are also described herein.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes. This application claims the benefit of U.S. Provisional Patent Application No. 62/706,035, filed Jul. 28, 2020, which is incorporated herein by reference in its entirety.

### FIELD

The present disclosure relates to a stimulus responsive polymer (SRP) that includes a homopolymer. Methods, films, and formulations employing an SRP are also described herein.

### BACKGROUND

During semiconductor fabrication, many surfaces are sensitive to airborne molecular contaminants (AMCs) in the surrounding environment. Queue-time can lead to exposure to the AMCs and unwanted interactions, such as oxidation, corrosion, and halogenation. Solutions include storing partially fabricated semiconductor substrates in nitrogen (N₂)-filled storage cassettes or rooms and using integrated tools that support multiple processes without breaking the vacuum on the substrates. These solutions are difficult and expensive to implement and pose safety and reliability concerns.

The background description provided herein is for the purpose of generally presenting the context of the present technology. Work of the presently named inventors, to the extent it is described in this background section, as well as aspects of the description that may not otherwise qualify as prior art at the time of filing, are neither expressly nor impliedly admitted as prior art against the present technology.

### SUMMARY

The present disclosure relates to a stimulus responsive polymer (SRP) that includes or is a homopolymer. In particular embodiments, the chemical characteristics of the SRP can be designed and tuned, e.g., to provide optimized deposition within particular feature sizes, residue-free removal, and/or less aggressive depolymerization. In a non-limiting instance, the SRP has a characteristic molecular weight (MW) that allows for filling of gaps, trenches, or features having minimized sizes that are difficult to address with traditional semiconductor processes. In another instance, the SRP allows for residue-free removal under mild conditions that do not damage sensitive substrates and surfaces.

Accordingly, in a first aspect, the present disclosure features a method including: depositing an SRP on a substrate. In particular embodiments, the SRP includes a homopolymer. In other embodiments, the homopolymer includes a MW (e.g., a weight-average MW) of from about 250 g/mol to about 1500 kg/mol and/or a ceiling temperature less than about 300° C. In yet other embodiments, said depositing thereby forms a film or a layer on a surface of the substrate. The film or layer can be provided on a top surface and/or a bottom surface of the substrate, as well as portions thereof. In other embodiments, the film or layer is provided within or in proximity to a feature (e.g., a trench, a gap, a structure, etc.) of the substrate.

In some embodiments, said depositing includes depositing a formulation including the SRP. In other embodiments, the formulation includes one or more additives. In particular embodiments, one or more additives are each present in an amount of from about 0.001 wt. % to about 25 wt. %. In other embodiments, a combination of a plurality of additives is present in an amount of from about 0.001 wt. % to about 25 wt. %. Non-limiting additives include one or more of a solvent, a plasticizer, an organic acid having a pKa more than or equal to 1, a photoacid generator, a thermal acid generator, and/or a dye.

In some embodiments, the method further includes (e.g., after said depositing): storing the film in an ambient condition, wherein the film provides protection for the surface of the substrate during storage.

In other embodiments, the method further includes (e.g., after said storing): removing the film from the surface of the substrate. Non-limiting operations for removing can include exposing the film to one or more stimuli, such as exposure to heat (e.g., continuous heat), a temperature ramp (e.g., ramping of from about 1° C./min to about 200° C./sec, in which such ramping can include decreasing or increasing the temperature), ultraviolet light (e.g., with or without vacuum; optionally at a temperature of from about 30° C. to about 700° C.; and/or optionally at a dosage of from about 0.1 mW/cm² to about 15 W/cm²), metastable neutrals (e.g., atoms from a noble gas plasma), acidic or basic vapors (e.g., at a temperature of from about 20° C. to about 200° C.), and/or plasma.

In some embodiments, the substrate includes a trench, a gap, or another feature. In particular embodiments, said depositing includes filling the trench or the gap with the SRP.

In other embodiments, the substrate includes a plurality of high aspect ratio structures with a first solvent. In particular embodiments, said depositing further includes displacing the first solvent with a solution including the SRP.

In some embodiments, the homopolymer includes a structure of one of formulas (I)-(XIII):

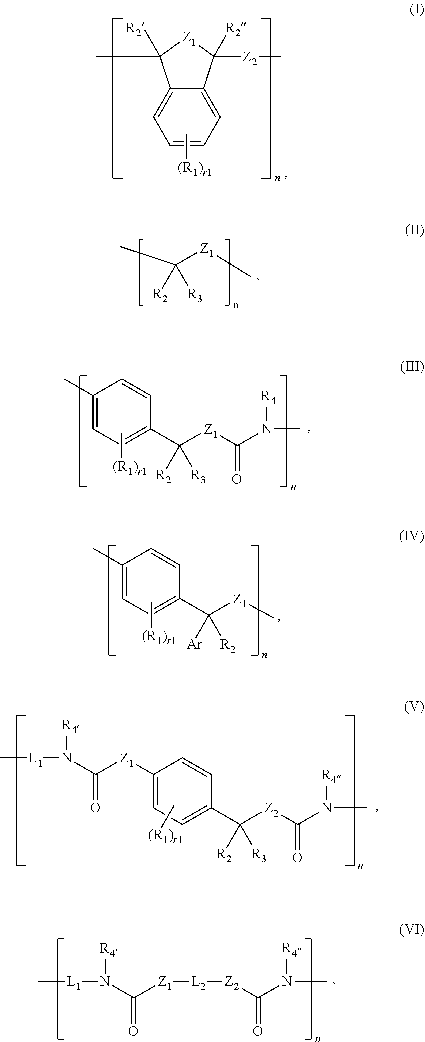

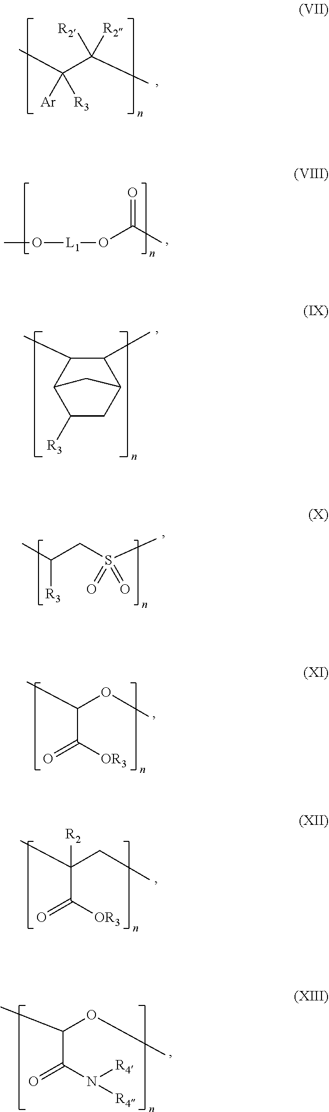

or a salt thereof, wherein:
each R₁ is, independently, H, optionally substituted alkyl, optionally substituted alkoxy, optionally substituted alkenyl, optionally substituted aryl, or halo;
each of R₂, R_{2′}, R_{2″}, and R₃ is, independently, H, optionally substituted alkyl, optionally substituted heteroalkyl, or optionally substituted aryl;
each of R₄, R_{4′}, and R_{4″} is, independently, H, optionally substituted alkyl, optionally substituted aminoalkyl, optionally substituted heteroalkyl, or R_{4′}, and R_{4″}, taken together with the nitrogen atom to which each are attached, form a heterocyclyl group, as defined herein;
Ar is optionally substituted aryl, optionally substituted alkyl, or optionally substituted aralkyl;
each of L₁ and L₂ is, independently, a covalent bond, optionally substituted alkylene, optionally substituted heteroalkylene, optionally substituted arylene, or optionally substituted cycloalkylene;
each of Z₁ and Z₂ is, independently, —O—, —S—, —CR₂R₃O—, —OCR₂R₃O—, —OCR₂R₃—, —CR₂R₃S—, —SCR₂R₃S—, or —SCR₂R₃—;
r1 is an integer from 1 to 4; and
n is from about 1 to about 100,000 (e.g., 2 to 100,000, 3 to 100,000, or 4 to 100,000); and
   wherein the homopolymer includes a linear polymer or a cyclic polymer.

In some embodiments, the homopolymer includes a structure of formula (Ia):

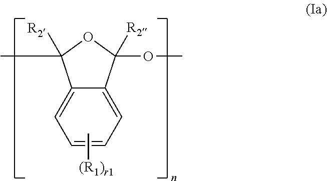

or a salt thereof, wherein R₁, R_{2′}, R_{2″}, r1, and n can be any described herein (e.g., such as for formula (I)). In particular embodiments, the homopolymer includes a linear polymer or a cyclic polymer.

In other embodiments, the homopolymer includes a structure of formula (Ib):

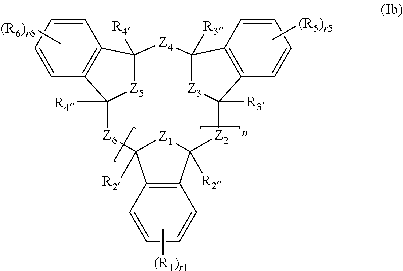

or a salt thereof, wherein:
each of R₁, R₅, and R₆ is, independently, H, optionally substituted alkyl, optionally substituted alkoxy, optionally substituted alkenyl, optionally substituted aryl, or halo;
each of R_{2′}, R_{2″}, R_{3′}, R_{3″}, R_{4′}, and R_{4″} is, independently, H, optionally substituted alkyl, or optionally substituted aryl;
each of Z₁, Z₂, Z₃, Z₄, Z₅, and Z₆ is, independently, —O—, —S—, —CR₂R₃O—, —OCR₂R₃O—, —OCR₂R₃—, —CR₂R₃S—, —SCR₂R₃S—, or —SCR₂R₃—, in which each of R₂ and R₃ is, independently, H, optionally substituted alkyl, or optionally substituted aryl;
each of r1, r5, and r6 is, independently, an integer from 1 to 4; and
n is from 2 to 100.

In yet other embodiments, the homopolymer includes a structure of formula (Ic):

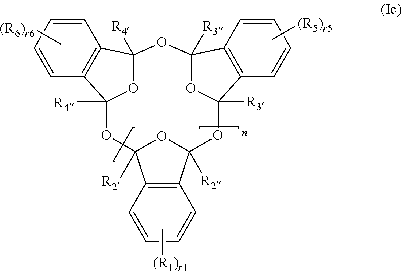

or a salt thereof, wherein R₁, R_{2′}, R_{2″}, R_{3′}, R_{3″}, R_{4′}, R_{4″}, R₅, R₆, r1, r5, r6, and n can be any described herein (e.g., such as for formula (Ib)).

In some embodiments, the film includes a protective film on a top surface or a bottom surface of the substrate. The protective film can be provided on a top surface, thereby protecting a sensitive surface of the substrate or any feature disposed on the substrate (e.g., from reactive species, such as airborne species, or other contaminants). Also, the protective film can be provided on a bottom surface, thereby acting as a backside coating to protect the substrate backside (e.g., from particles or mechanical scratching). In particular embodiments, the method further includes (e.g., after said depositing): storing the protective film and the substrate in an ambient condition. In other embodiments, the method further includes (e.g., after said storing): removing the protective film from the surface of the substrate.

In some embodiments, the substrate includes a gap. In particular embodiments, said depositing includes: depositing the SRP to fill a gap on the surface of a substrate, thereby forming a gapfill within the gap. In other embodiments, the method further includes (e.g., after said depositing): removing the gapfill from the surface of the substrate.

In particular embodiments, the substrate includes a plurality of high aspect ratio (HAR) structures disposed on a substrate. Optionally, a solvent can be provided in a gap present between the plurality of HAR structures. In some embodiments, said depositing includes: depositing the SRP to displace a first solvent from the plurality of HAR structures disposed on the substrate. In other embodiments, the method further includes (e.g., after said depositing):
drying the substrate to form a film including the SRP. In yet other embodiments, the method includes (e.g., after said drying): removing the film from the substrate.

In a second aspect, the present disclosure encompasses a method (e.g., of making an SRP) including: reacting a monomer in the presence of a reagent; and terminating polymerization of the monomer to provide the SRP (e.g., any described herein). In particular embodiments, the monomer includes a structure of one of formulas (I)-(XV), (Ia), (Ib), (Ic), or a salt thereof (e.g., in which n is 1). In other embodiments, the method further includes (e.g., after said terminating): depositing the SRP on a substrate or a feature (e.g., any described herein).

In a third aspect, the present disclosure features a structure including: a semiconductor substrate having a top surface and a bottom surface; and a layer of SRP that is disposed on the top surface and/or the bottom surface of the semiconductor substrate. In particular embodiments, the layer is further disposed on a feature provided by the substrate. Non-limiting features include a trench, a gap, a pillar, a device, a high aspect ratio (HAR) structure, or others.

In some embodiments, the layer is configured to reduce permeation (e.g., sorption and/or diffusion) of one or more contaminants or reactive airborne molecules to a surface of the substrate and/or to block one or more reactive sites disposed on a surface of the substrate. Non-limiting contaminants include oxygen, water, and halogens (e.g., fluorine).

In other embodiments, the structure further includes: a plurality of HAR structures disposed on the top surface of the substrate. In particular embodiments, a gap is present between at least two of the HAR structures, and the layer substantially fills the gap. In some embodiments, the gap has an aspect ratio of from about 0.5:1 to about 300:1.

In a fourth aspect, the present disclosure features a formulation including: about 0.1 wt. % to about 50 wt. % of an SRP (e.g., any herein); and a solvent. In some embodiments, the formulation further includes: about 0.001 wt. % to about 25 wt. % of an additive selected from 30 a plasticizer, an organic acid having a pKa more than or equal to 1, a photoacid generator, a thermal acid generator, and/or a dye.

In any embodiment herein, the SRP has a MW (e.g., a weight-average MW) of from about 250 g/mol to about 1500 kg/mol (e.g., from about 250 g/mol to 500 g/mol, 250 g/mol to 1000 g/mol, 250 g/mol to 2 kg/mol, 250 g/mol to 10 kg/mol, 250 g/mol to 50 kg/mol, 250 g/mol to 100 kg/mol, 250 g/mol to 250 kg/mol, 250 g/mol to 500 kg/mol, 250 g/mol to 750 kg/mol, 250 g/mol to 1000 kg/mol, 500 g/mol to 1000 g/mol, 500 g/mol to 2 kg/mol, 500 g/mol to 10 kg/mol, 500 g/mol to 50 kg/mol, 500 g/mol to 100 kg/mol, 500 g/mol to 250 kg/mol, 500 g/mol to 500 kg/mol, 500 g/mol to 750 kg/mol, 500 g/mol to 1000 kg/mol, 500 g/mol to 1500 kg/mol, 1 kg/mol to 2 kg/mol, 1 kg/mol to 10 kg/mol, 1 kg/mol to 50 kg/mol, 1 kg/mol to 100 kg/mol, 1 kg/mol to 250 kg/mol, 1 kg/mol to 500 kg/mol, 1 kg/mol to 750 kg/mol, 1 kg/mol to 1000 kg/mol, and 1 kg/mol to 1500 kg/mol).

In any embodiment herein, the SRP has a ceiling temperature less than about 300° C. In particular embodiments, the ceiling temperature is less than about 300° C., 250° C., 200° C., 150° C., 100° C., 90° C., 80° C., 75° C., 60° C., 50° C., 40° C., 30° C., 25° C., 20° C., 15° C., 10° C., 5° C., 0° C., −10° C., −20° C., −30° C., −40° C., −50° C., or less.

In any embodiment herein, the SRP has a ceiling temperature of from about −50° C. to about 300° C. In particular embodiments, the ceiling temperature is from about −50° C. to 250° C., −50° C. to 200° C., −50° C. to 150° C., −50° C. to 100° C., −50° C. to 50° C., −50° C. to 30° C., −50° C. to 10° C., −50° C. to 0° C., −50° C. to −10° C., −50° C. to −20° C., −50° C. to −30° C., −50° C. to −40° C., −40° C. to 250° C., −40° C. to 200° C., −40° C. to 150° C., −40° C. to 100° C., −40° C. to 50° C., −40° C. to 30° C., −40° C. to 10° C., −40° C. to 0° C., −40° C. to −10° C., −40° C. to −20° C., −40° C. to −30° C., −30° C. to 250° C., −30° C. to 200° C., −30° C. to 150° C., −30° C. to 100° C., −30° C. to 50° C., −30° C. to 30° C., −30° C. to 10° C., −30° C. to 0° C., −30° C. to −10° C., −30° C. to −20° C., −20° C. to 250° C., −20° C. to 200° C., −20° C. to 150° C., −20° C. to 100° C., −20° C. to 50° C., −20° C. to 30° C., −20° C. to 10° C., −20° C. to 0° C., −20° C. to −10° C., −10° C. to 250° C., −10° C. to 200° C., −10° C. to 150° C., −10° C. to 100° C., −10° C. to 50° C., −10° C. to 30° C., −10° C. to 10° C., and −10° C. to 0° C.

In any embodiment herein, the SRP is a homopolymer that includes a structure of one of formulas (I)-(XIII), (Ia), (Ib), (Ic), or a salt thereof.

In any embodiment herein, the SRP is a copolymer that includes a structure of one of formulas (I)-(XV), (Ia), (Ib), (Ic), or a salt thereof.

In any embodiment herein, the SRP, SRP layer, or SRP film can be removed by exposure to one or more stimuli. Non-limiting stimulus can include exposure to heat, a temperature ramp (e.g., ramping of from about 1° C./min to about 200° C./sec, in which such ramping can include decreasing or increasing the temperature), ultraviolet (UV) light (e.g., with or without vacuum; optionally at a temperature of from about 30° C. to about 700° C.; and/or optionally at a dosage of from about 0.1 mW/cm² to about 15 W/cm²), one or more metastable neutrals (e.g., atoms from a noble gas plasma), acidic or basic chemistries (e.g., as vapors and optionally at a temperature of from about 20° C. to about 200° C.), and/or plasma. In particular embodiments, exposure to heat can include a constant temperature. In other embodiments, exposure to heat can include any useful temperature profile with any useful temperature ramp rates (e.g., of increasing or decreasing temperature) and any useful temperature holds. Exposure to UV light can optionally include vacuum and can include any useful temperature (e.g., from about 20° C. to about 700° C., such as about 20° C. to 100° C., 20° C. to 200° C., 20° C. to 300° C., 20° C. to 400° C., 20° C. to 500° C., 20° C. to 600° C., 30° C. to 100° C., 30° C. to 200° C., 30° C. to 300° C., 30° C. to 400° C., 30° C. to 500° C., 30° C. to 600° C., 30° C. to 700° C., 40° C. to 100° C., 40° C. to 200° C., 40° C. to 300° C., 40° C. to 400° C., 40° C. to 500° C., 40° C. to 600° C., 40° C. to 700° C., 50° C. to 100° C., 50° C. to 200° C., 50° C. to 300° C., 50° C. to 400° C., 50° C. to 500° C., 50° C. to 600° C., or 50° C. to 700° C.).

In any embodiment herein, the SRP, SRP layer, or SRP film is configured to reduce permeation of one or more reactive airborne molecules to a surface of a feature or a substrate.

In any embodiment herein, the SRP, SRP layer, or SRP film is configured to block one or more reactive sites disposed on a surface of a feature or a substrate. Additional embodiments are described herein.

### DEFINITIONS

By “alkenyl” is meant an optionally substituted C₂₋₂₄ alkyl group having one or more double bonds. The alkenyl group can be cyclic (e.g., C₃₋₂₄ cycloalkenyl) or acyclic. The alkenyl group can also be substituted or unsubstituted. For example, the alkenyl group can be substituted with one or more substitution groups, as described herein for alkyl.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” and the prefix “alk” is meant a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃₋₂₄ cycloalkyl) or acyclic. The alkyl group can be branched or unbranched. The alkyl group can also be substituted or unsubstituted. For example, the alkyl group can be substituted with one, two, three or, in the case of alkyl groups of two carbons or more, four substituents independently selected from the group consisting of: (1) C₁₋₆ alkoxy (e.g., —O-Ak, wherein Ak is optionally substituted C₁₋₆ alkyl); (2) C₁₋₆ alkylsulfinyl (e.g., —S(O)-Ak, wherein Ak is optionally substituted C₁₋₆ alkyl); (3) C₁₋₆ alkylsulfonyl (e.g., —SO₂-Ak, wherein Ak is optionally substituted C₁₋₆ alkyl); (4) amino (e.g., —NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (5) aryl; (6) arylalkoxy (e.g., -O-L-Ar, wherein L is a bivalent form of optionally substituted alkyl and Ar is optionally substituted aryl); (7) aryloyl (e.g., —C(O)—Ar, wherein Ar is optionally substituted aryl); (8) azido (e.g., —N₃); (9) cyano (e.g., —CN); (10) carboxyaldehyde (e.g., —C(O)H); (11) C₃₋₈ cycloalkyl (e.g., a monovalent saturated or unsaturated non-aromatic cyclic C₃₋₈ hydrocarbon group); (12) halo (e.g., F, Cl, Br, or I); (13) heterocyclyl (e.g., a 5-, 6- or 7-membered ring, unless otherwise specified, containing one, two, three, or four non-carbon heteroatoms, such as nitrogen, oxygen, phosphorous, sulfur, or halo); (14) heterocyclyloxy (e.g., —O-Het, wherein Het is heterocyclyl, as described herein); (15) heterocyclyloyl (e.g., —C(O)-Het, wherein Het is heterocyclyl, as described herein); (16) hydroxyl (e.g., —OH); (17) N-protected amino; (18) nitro (e.g., —NO₂); (19) oxo (e.g., ═O); (20) C₃₋₈ spirocyclyl (e.g., an alkylene or heteroalkylene diradical, both ends of which are bonded to the same carbon atom of the parent group); (21) C₁₋₆ thioalkoxy (e.g., —S-Ak, wherein Ak is optionally substituted C₁₋₆ alkyl); (22) thiol (e.g., —SH); (23) —CO₂R^{A}, where R^{A} is selected from the group consisting of (a) hydrogen, (b) C₁₋₆ alkyl, (c) C₄₋₁₈ aryl, and (d) (C₄₋₁₈ aryl) C₁₋₆ alkyl (e.g., -L-Ar, wherein L is a bivalent form of optionally substituted alkyl group and Ar is optionally substituted aryl); (24) —C(O)NR^{B}R^{C}, where each of R^{B} and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -L-Ar, wherein L is a bivalent form of optionally substituted alkyl group and Ar is optionally substituted aryl); (25) —SO₂R^{D}, where R^{D} is selected from the group consisting of (a) C₁₋₆ alkyl, (b) C₄₋₁₈ aryl, and (c) (C₄₋₁₈ aryl) C₁₋₆ alkyl (e.g., -L-Ar, wherein L is a bivalent form of optionally substituted alkyl group and Ar is optionally substituted aryl); (26) —SO₂NR^{E}R^{F}, where each of R^{E} and R^{F} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -L-Ar, wherein L is a bivalent form of optionally substituted alkyl group and Ar is optionally substituted aryl); and (27) —NR^{G}R^{H}, where each of RG and RH is, independently, selected from the group consisting of (a) hydrogen, (b) an N-protecting group, (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., L-Ar, wherein L is a bivalent form of optionally substituted alkyl group and Ar is optionally substituted aryl), (h) C₃₋₈ cycloalkyl, and (i) (C₃₋₈ cycloalkyl) C₁₋₆ alkyl (e.g., -L-Cy, wherein L is a bivalent form of optionally substituted alkyl group and Cy is optionally substituted cycloalkyl, as described herein), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene” is meant a multivalent (e.g., bivalent) form of an alkyl group, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. The alkylene group can be branched or unbranched. The alkylene group can also be substituted or unsubstituted. For example, the alkylene group can be substituted with one or more substitution groups, as described herein for alkyl.

By “alkynyl” is meant an optionally substituted C₂₋₂₄ alkyl group having one or more triple bonds. The alkynyl group can be cyclic or acyclic and is exemplified by ethynyl, 1-propynyl, and the like. The alkynyl group can also be substituted or unsubstituted. For example, the alkynyl group can be substituted with one or more substitution groups, as described herein for alkyl.

By “amino” is meant —NR^{N1}R^{N2}, where each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein.

By “aminoalkyl” is meant an alkyl group, as defined herein, substituted by an amino group, as defined herein.

By “aralkyl” or “arylalkyl” is meant an aryl group, as defined herein, attached to the parent molecular group through an alkylene group, as defined herein. In some embodiments, the aralkyl group is -Ak-Ar, in which Ak is an optionally substituted alkylene, as defined herein, and Ar is an optionally substituted aryl, as defined herein. The aralkyl group can be substituted or unsubstituted. For example, the aralkyl group can be substituted with one or more substitution groups, as described herein for aryl and/or alkyl. Exemplary unsubstituted aralkyl groups are of from 7 to 16 carbons (C₇₋₁₆ aralkyl), as well as those having an aryl group with 4 to 18 carbons and an alkylene group with 1 to 6 carbons (i.e., (C₄₋₁₈ aryl)C₁₋₆ alkyl).

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes “heteroaryl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents, such as any described herein for alkyl. In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for aryl.

By “(aryl)(alkyl)ene” is meant a bivalent form including an arylene group, as described herein, attached to an alkylene or a heteroalkylene group, as described herein. In some embodiments, the (aryl)(alkyl)ene group is -L-Ar— or -L-Ar-L- or —Ar-L-, in which Ar is an arylene group and each L is, independently, an optionally substituted alkylene group or an optionally substituted heteroalkylene group.

By “azido” is meant an —N₃ group.

By “azidoalkyl” is meant an azido group attached to the parent molecular group through an alkyl group, as defined herein.

By “carboxyaldehyde” is meant a —C(O)H group.

By “carboxyalkyl” is meant an alkyl group, as defined herein, substituted by a carboxyl group, as defined herein.

By “carboxyl” is meant a —CO₂H group.

By “cyano” is meant a —CN group.

By “cycloalkenyl” is meant a non-aromatic carbon-based ring composed of three to ten carbon atoms and containing at least one double bound, i.e., C═C. Examples of cycloalkenyl groups include, but are not limited to, cyclopropenyl, cyclobutenyl, cyclopentenyl, cyclopentadienyl, cyclohexenyl, cyclohexadienyl, and the like.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.]heptyl, and the like. The cycloalkyl group can also be substituted or unsubstituted. For example, the cycloalkyl group can be substituted with one or more groups including those described herein for alkyl.

By “cycloalkylene” is meant a multivalent (e.g., bivalent) form of a cycloalkyl group, as described herein. Exemplary cycloalkylene groups include cyclopropylene, cyclobutylene, cyclopentylene, cyclohexylene, cyclohexenylene, cyclohexadienylene, etc. In some embodiments, the cycloalkylene group is a C₃₋₆, C₃₋₁₂, C₃₋₁₆, C₃₋₁₈, C₃₋₂₀, or C₃₋₂₄ cycloalkylene group. The cycloalkylene group can be branched or unbranched. The cycloalkylene group can also be substituted or unsubstituted. For example, the cycloalkylene group can be substituted with one or more substitution groups, as described herein for alkyl.

By “fluoroacid” is meant A¹CO₂H, where A¹ is an optionally substituted alkyl or an optionally substituted aryl substituted with one or more fluoro (F).

By “ester” as used herein is meant —OC(O)A¹ or —C(O)OA¹, where A¹ can be an alkyl, alkenyl, alkynyl, aryl, heteroaryl, cycloalkyl, cycloalkenyl, heterocycloalkyl, or heterocycloalkenyl group, as described herein.

By “ether” as used herein is meant A¹OA², where A¹ and A² can be, independently, an alkyl, alkenyl, alkynyl, aryl, heteroaryl, cycloalkyl, cycloalkenyl, heterocycloalkyl, or heterocycloalkenyl group, as described herein.

By “halo” is meant F, Cl, Br, or I.

By “haloalkyl” is meant an alkyl group, as defined herein, substituted with one or more halo.

By “heteroalkyl” is meant an alkyl group, as defined herein, containing one, two, three, or four non-carbon heteroatoms (e.g., independently selected from the group consisting of nitrogen, oxygen, phosphorous, sulfur, selenium, or halo).

By “heteroalkylene” is meant an alkylene group, as defined herein, containing one, two, three, four, or more non-carbon heteroatoms (e.g., independently selected from the group consisting of nitrogen, oxygen, phosphorous, sulfur, selenium, or halo). In some embodiments, the heteroalkylene group is -Ak-X—, —X-Ak-, -(Ak-X)ₕ₁-Ak-, or —X-(Ak-X)ₕ₁—, in which Ak is an optionally substituted alkylene, as defined herein, X is or includes a non-carbon heteroatom (e.g., —O—, —S—, or —NR^{N1}—, which R^{N1} is H, optionally alkyl, or optionally substituted aryl), and h1 is an integer from 1 to 5. The heteroalkylene group can be substituted or unsubstituted. For example, the heteroalkylene group can be substituted with one or more substitution groups, as described herein for alkyl. The heteroalkylene group can be linear or cyclic, such as a bivalent form of a heterocyclyl group formed by removing a hydrogen from a heterocyclyl group, as described herein. Exemplary cyclic heteroalkylene groups include piperdylidene, quinolinediyl, etc.

The term “heterocycloalkenyl” is a type of cycloalkenyl group, as defined herein, in which at least one of the carbon atoms of the ring is substituted with O, S, N, or NH. The cycloalkenyl group and heterocycloalkenyl group can be substituted or unsubstituted. The cycloalkenyl group and heterocycloalkenyl group can be substituted with one or more groups including, but not limited to, alkyl, alkoxy, alkenyl, alkynyl, aryl, heteroaryl, carboxyaldehyde, amino, carboxyl, sulfonic acid, sulfinic acid, fluoroacid, phosphonic acid, ester, ether, halo, hydroxyl, ketone, nitro, cyano, azido, silyl, sulfonyl, sulfinyl, or thiol, as described herein.

The term “heterocycloalkyl” is a type of cycloalkyl group, as defined herein, in which at least one of the carbon atoms and its attached hydrogen atoms, if any, are replaced by O, S, N, or NH. The heterocycloalkyl group and heterocycloalkenyl group can be substituted or unsubstituted. The cycloalkyl group and heterocycloalkyl group can be substituted with one or more groups including, but not limited to, alkyl, alkoxy, alkenyl, alkynyl, aryl, heteroaryl, carboxyaldehyde, amino, carboxyl, sulfonic acid, sulfinic acid, fluoroacid, phosphonic acid, ester, ether, halo, hydroxyl, ketone, nitro, cyano, azido, silyl, sulfonyl, sulfinyl, or thiol, as described herein.

By “heterocyclyl” is meant a 3-, 4-, 5-, 6- or 7-membered ring (e.g., a 5-, 6- or 7-membered ring), unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benzisothiazolyl, benzisoxazolyl, benzodiazepinyl, benzodiazocinyl, benzodihydrofuryl, benzodioxepinyl, benzodioxinyl, benzodioxanyl, benzodioxocinyl, benzodioxolyl, benzodithiepinyl, benzodithiinyl, benzodioxocinyl, benzofuranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotriazinonyl, benzotriazinyl, benzotriazolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl benzylsultimyl, bipyrazinyl, bipyridinyl, carbazolyl (e.g., 4H-carbazolyl), carbolinyl (e.g., β-carbolinyl), chromanonyl, chromanyl, chromenyl, cinnolinyl, coumarinyl, cytdinyl, cytosinyl, decahydroisoquinolinyl, decahydroquinolinyl, diazabicyclooctyl, diazetyl, diaziridinethionyl, diaziridinonyl, diaziridinyl, diazirinyl, dibenzisoquinolinyl, dibenzoacridinyl, dibenzocarbazolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, dioxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., 1H-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothioxolyl, naphthotriazolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiopyranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotriazolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, and the like, as well as modified forms thereof (e.g., including one or more oxo and/or amino) and salts thereof. The heterocyclyl group can be substituted or unsubstituted. For example, the heterocyclyl group can be substituted with one or more substitution groups, as described herein for aryl.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like.

By “ketone” is meant A¹C(O)A², where A¹ and A² can be, independently, an alkyl, haloalkyl, alkenyl, alkynyl, aryl, heteroaryl, cycloalkyl, cycloalkenyl, heterocycloalkyl, or heterocycloalkenyl group, as described herein.

By “nitro” is meant an —NO₂ group.

By “oxy” is meant —O—.

By “phosphonic acid” is meant —P(O)(OH)₂.

By “silyl” is meant —SiA¹A²A³, where each of A¹, A², and A³ can be, independently, an alkyl, haloalkyl, alkenyl, alkynyl, aryl, heteroaryl, cycloalkyl, cycloalkenyl, heterocycloalkyl, or heterocycloalkenyl group, as described herein

By “sulfinic acid” is meant —S(O)OH.

By “sulfinyl” is meant —S(O)A¹, where A¹ can be hydrogen, an alkyl, haloalkyl, alkenyl, alkynyl, aryl, heteroaryl, cycloalkyl, cycloalkenyl, heterocycloalkyl, or heterocycloalkenyl group, as described herein.

By “sulfonic acid” is meant —S(O)₂OH.

By “sulfonyl” is meant —S(O)₂A¹, where A¹ can be hydrogen, an alkyl, halogenated alkyl, alkenyl, alkynyl, aryl, heteroaryl, cycloalkyl, cycloalkenyl, heterocycloalkyl, or heterocycloalkenyl group, as described herein.

By “thio” is meant an —S— group.

By “thiol” is meant an —SH group.

As used herein, the term “about” means +/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

Other features and advantages of the invention will be apparent from the following description and the claims.

### BRIEF DESCRIPTION OF THE DRAWINGS

FIG. 1A-1C shows flow diagrams showing certain operations in examples semiconductor fabrication processes that use stimulus response polymers (SRPs). Provided are (A) a method 100 for depositing on sensitive surface, (B) a method 120 for depositing to fill a trench or a gap, and (C) a method 140 for depositing on a high aspect ratio (HAR) structure.

FIG. 2A-2C shows side cross-sectional view of various structures. Provided are (A) a structure 200 including an SRP film 203; (B) another structure 220 having a filled trench 222; and (C) yet another structure 240 having an SRP film 243 disposed between a plurality of high aspect ratio (HAR) structures 242.

FIG. 3A-3B shows process flow diagrams for non-limiting methods of removing SRP.

FIG. 4 is a functional block diagram of an example of a substrate processing system including multiple substrate processing tools and a storage buffer according to the present disclosure.

### DETAILED DESCRIPTION

Stimuli responsive polymers (SRPs) may be used in semiconductor fabrication processes as sacrificial layers that can be later removed. Low ceiling temperature SRPs can be spontaneously removed when exposed to stimuli such as mildly elevated temperatures or acidic vapors, avoiding aggressive wet or dry removal chemistries that may harm the substrate surface. Other processes to remove SRPs are described herein. In contrast, other coatings (e.g., silicon nitride) can provide hermetic encapsulation but require aggressive chemistry for removal.

During semiconductor fabrication, many surfaces are sensitive to the surrounding environment, which can lead to undesirable interactions and necessitate the need for queue-time management solutions. These interactions include unwanted oxidation, corrosion, and/or halogenation. SRP layers can protect environmentally sensitive surfaces and substrates from chemical modification. For instance, SRPs can protect surfaces from airborne molecular contaminants (AMCs) and block reactive site disposed on the substrate. Sensitive surfaces include substrates during semiconductor processing, such as integrated circuit (IC) fabrication.

Such sacrificial films can provide queue-time extension. In one instance, the SRP film can be a thin sacrificial polymer configured to protect sensitive thin-films for extended periods when the materials are vulnerable to external threats. The sacrificial surface protection layers can eventually be removed by triggering spontaneous depolymerization and vaporization of the protection layer above its ceiling temperature with the appropriate stimuli (e.g., thermal and/or electromagnetic), thus minimizing the impact on the sensitive surfaces. Examples of surfaces that can be sensitive to environmental queue-time effects include but are not limited to silicon, silicon/germanium (Si/Ge), copper, tungsten, cobalt, and titanium nitride (TiN).

Furthermore, SRPs can be used to brace HAR structures during processing, thereby minimizing collapse of such features. Depositing a low ceiling temperature homopolymer onto HAR structures can both protect the surfaces from being modified, as well as prevent collapse from capillary forces during solvent drying by mechanically bracing the features. If the homopolymer brace is removed properly, it also enables collapse-free drying of high aspect ratio structures.

In particular, the SRP can be a low ceiling temperature (T_{c}) homopolymer that is thermodynamically unstable at room temperature. T_{c} is the temperature at which both the polymer and its monomers are present at equilibrium. Below T_{c}, it is a polymer and above T_{c} it is monomer. Such low T_{c} polymers can be kinetically trapped as polymers with excellent shelf-life at temperatures well above T_{c}. For example, poly(phthalaldehyde) (PPHA) has a T_{c} of −40° C. but is stable at room temperature for 2.5 years. Stability is achieved by kinetically inhibiting the mechanism of depolymerization. In some non-limiting embodiments, benefits for employing a homopolymer as an SRP includes simplified and/or less costly polymerization to form a film, as well as simplified synthesis due to fewer variables.

The SRP can be deposited in any useful manner. For instance, wet deposition of the homopolymer protection layer can include spin coating, in which the formulation of the spin coating solution and eventual protection layer can be important for its performance. The choice of solvent that is used for the spin coating formulation can impact the amount of residual solvent that remains in the homopolymer thin films. Residual solvent can plasticize the homopolymer, lowering its glass transition temperature. By plasticizing the homopolymers, we can better fill HAR features and relax stresses from the spin coating process at temperatures below the degradation temperature of the homopolymer.

Furthermore, the homopolymer can be formulated with weak organic acids (e.g., pKa≥1). These weak organic acids can catalyze the degradation of the SRP without compromising the film stability. By catalyzing the homopolymer degradation, we can lower the onset degradation temperature and increase the degradation rate.

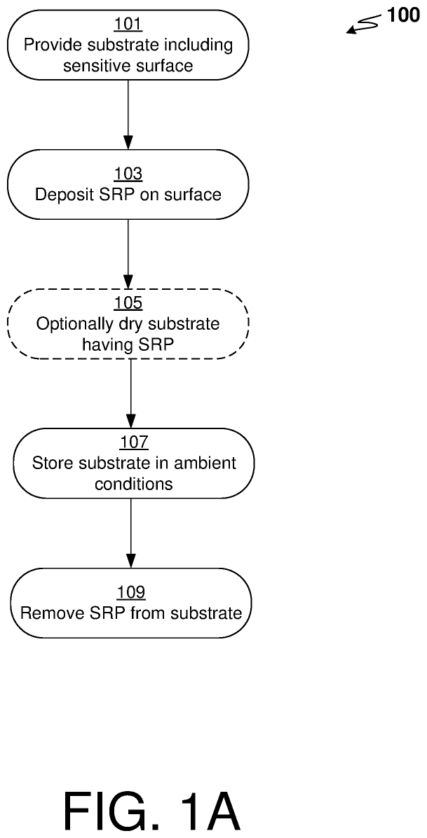

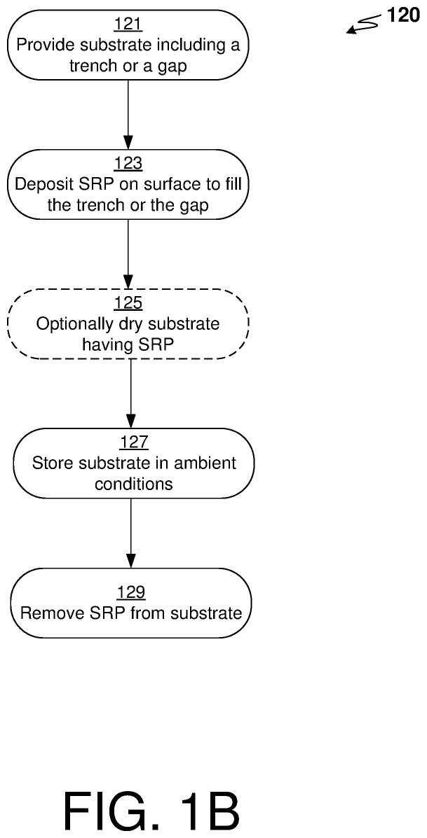

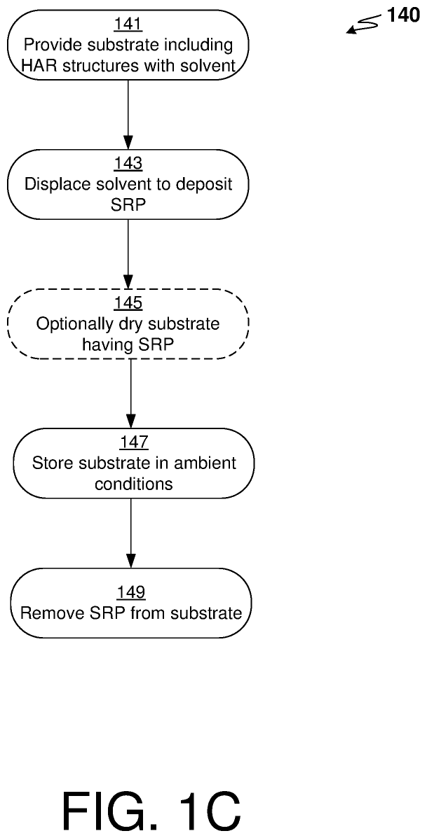

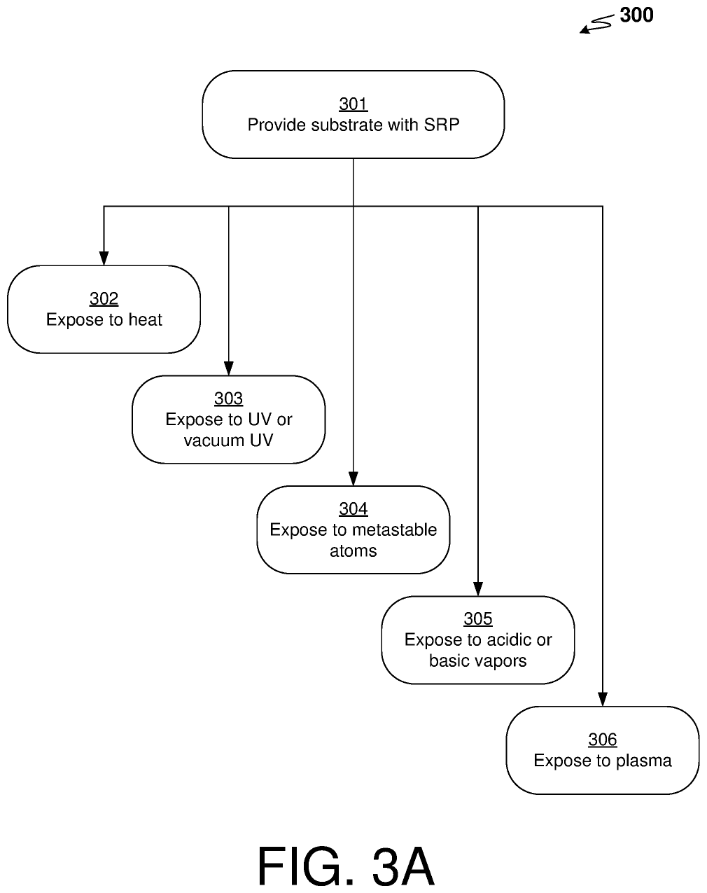

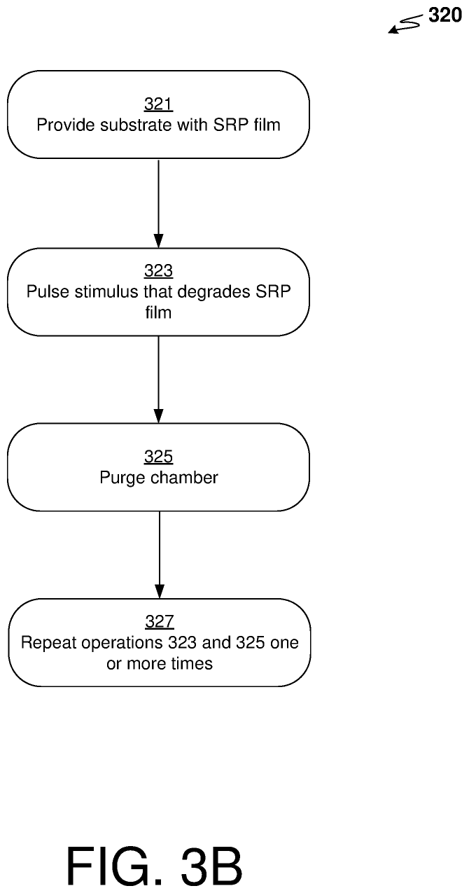

Examples of processes that involve the use of sacrificial SRPs are described below with reference to FIG. 1A-1C, with further details of the removal process provided with reference to FIG. 3A-3B. Turning to FIG. 1A, an example of a method 100 for protecting a sensitive surface is shown. First at an operation 101, a substrate including a sensitive surface is provided.

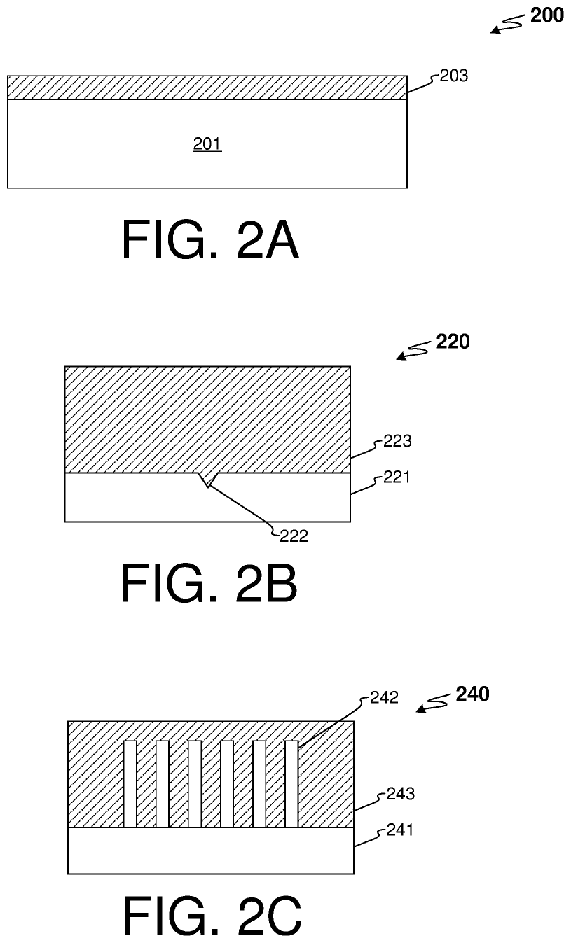

Next in an operation 103, the SRP is deposited on the surface, in which the SRP can be deposited as a formulation. Optionally, the substrate is then dried in an operation 105. The SRP solidifies as the liquid portion solution is removed, thereby forming a film. The substrate having the SRP can be stored in an operation 107. A non-limiting structure 200 having such a film 203 disposed upon a substrate 201 is provided in FIG. 2A.

Then, the substrate is exposed to a stimulus to degrade all of or only a portion of the SRP, thereby removing the SRP from the substrate in an operation 109. Volatile monomers or fragments from the degraded polymer can be removed. As described further below, operation 109 may involve controlled exposure to a condition, a compound, or two reactants that react to form a compound that degrades the SRP. The stimulus can be any that scissions bonds of the SRP to degrade it. In some embodiments, the stimulus includes heat or radiation. In other embodiments, the compound is a relatively strong acid or base.

In FIG. 1B, an example of a method 120 for filling a trench or a gap is shown. First at an operation 121, a substrate including a trench or a gap is provided. Next in an operation 123, the SRP is deposited on the surface to fill the trench or the gap. Optionally, the substrate is then dried in an operation 125. The SRP solidifies to form a film, and a non-limiting structure 220 having such a film 223 disposed within a trench 222 on a substrate 221 is provided in FIG. 2B. The film can then be stored in an operation 127, and removal occurs in an operation 129.

The substrate is exposed to a stimulus to degrade all of or only a portion of the SRP, thereby removing the SRP from the substrate in an operation 109. Volatile monomers or fragments from the degraded polymer can be removed. Removing an SRP from a substrate can include controlled degradation of the entire SRP film or a portion thereof.

As described further below, operation 109 may involve controlled exposure to a condition, a compound, or two reactants that react to form a compound that degrades the SRP. The stimulus can be any that scissions bonds of the SRP to degrade it. In some embodiments, the stimulus includes heat or radiation. In other embodiments, the compound is a relatively strong acid or base.

Turning to FIG. 1C, an example of a method 140 for bracing HAR structures using an SRP is shown. First at an operation 141, a substrate including HAR structures with a solvent is provided. HAR structures are structures having high aspect ratios (ARs), e.g., at least 8, 10, 20, 30, 40, or 80. The substrate may be provided, for example, after a wet etch or cleaning operation and have solvent associated with the prior operation. In some embodiments, the solvent in operation 141 may be a transitional solvent if the prior solvent is not chemically compatible with the SRP solution.

Next in an operation 143, the solvent is displaced with a solution that includes an SRP. The substrate is then dried in an optional operation 145. The SRP solidifies as the liquid portion solution is removed, and the SRP fills the HAR structures. A mechanical brace forms in the HAR structures to prevent collapse of the structures due to capillary forces that are generated during solvent drying. A non-limiting structure 240 having such a film 243 on and between a plurality of HAR structures 242 disposed on a substrate 241 is provided in FIG. 2C.

The substrate having the SRP can be stored in an operation 147. Then, the substrate is exposed to a stimulus to degrade all of or only a portion of the SRP, thereby removing the SRP from the substrate in an operation 149.

Several methods have been developed to achieve residue-free removal of SRPs without modifying the sensitive substrates. One method for depolymerizing the material includes exposing the polymer to elevated temperature under vacuum conditions. This method can lead to a rapid volatilization of the polymer, however angstrom-level residues, composed of char and residual monomer, often remain on the surface.

SRPs can be removed by using a less aggressive trigger, such as light or mild temperatures. These sacrificial polymers could allow protection of the sensitive surfaces and subsequent removal of the barrier film without exposing the surfaces to aggressive plasmas or wet chemical solutions. For certain challenging applications, there may be limitations to the temperature at which the substrates can be exposed, or extremely stringent contamination or throughput requirements. The SRPs and films thereof can be designed to address these applications. In some non-limiting instances, benefits for employing a homopolymer as an SRP may include a stronger driving force for depolymerization and/or a lower likelihood of having side reactions during unzipping, as compared to copolymers.

Alternative homopolymer removal processes can provide lower contamination levels. In some instance, SRP removal processes provide a lower contamination level with removal conditions that are milder than that for silicon nitride removal. In one such process, the homopolymer is exposed to long-lived metastable species from a noble gas plasma under vacuum at elevated temperature. In another process, the homopolymer is exposed to infrared (IR) or ultraviolet (UV) radiation at elevated temperature while under vacuum. Other processes include high temperature exposure (e.g., about 50° C. to about 800° C.) under vacuum conditions (e.g., <760 Torr) for a limited exposure time. Another process can include simultaneous high temperature exposure and radiation exposure by either UV or IR, which are under vacuum. Yet another process can include simultaneous high temperature exposure and noble gas metastable exposure, which are under vacuum. In particular embodiments, these removal processes have also shown low contamination without increasing the surface modification of the sensitive substrates.

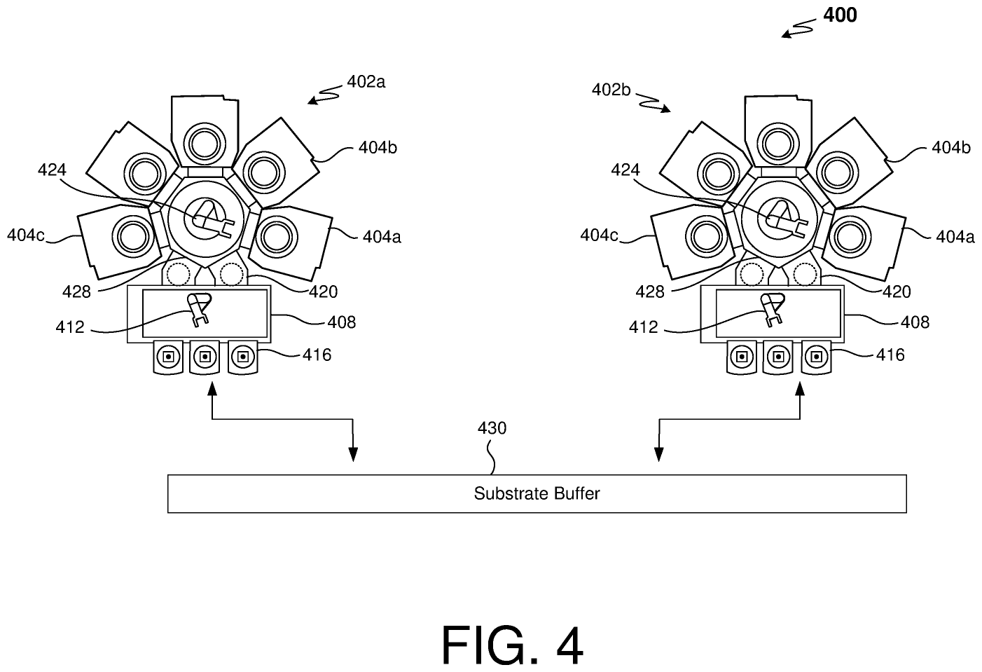

FIG. 3A-3B shows process flow diagrams showing further examples of a method of controlled exposure to a stimulus to degrade the SRP. Referring to FIG. 3A, a substrate is provided with SRP film in an operation 301. Operations 302-306 provide exposure to various types of stimuli, in which operations 302-306 may be used alone or in combination. Examples of apparatus that the substrate may be provided to are described below with reference to FIG. 4. In some embodiments, operation 301 involves providing the substrate to a processing chamber. In other embodiments, the substrate is in the chamber from a previous processing operation. The SRP may be provided in a variety of forms—for example, in a gap between features of a structure or as blanket film on all or part of a substrate.

Within the chamber, the substrate can be exposed to heat in an operation 302. Heat can be provided as a constant temperature hold. Alternatively, heat can be provided as a ramped temperature, in which increasing or decreasing temperature ramping can be used between temperature holds. Such thermal energy can provide sufficient energy to depolymerize the SRP by providing heat at a temperature that is above the T_{c}. Such conditions can include exposure to a temperature of up to 400° C. for an SRP having a T_{c} that is below 400° C., in which the SRP is kinetically trapped below the T_{c}. In other embodiments, thermal exposure can include a temperature from about 50° C. to about 800° C. (e.g., about 50° C. to 150° C., 50° C. to 300° C., 50° C. to 500° C., 150° C. to 300° C., 150° C. to 400° C., 150° C. to 500° C., 200° C. to 400° C., 200° C. to 500° C., 200° C. to 600° C., 250° C. to 500° C., 250° C. to 600° C., 300° C. to 500° C., 300° C. to 550° C., 300° C. to 600° C., etc.). In particular embodiments, thermal exposure includes from about 300° C. to about 500° C. (e.g., for removing films including pure SRP). In other embodiments, thermal exposure includes exposure to an elevated temperature (e.g., up to 800° C.) with a fast ramp rate and a shorter time. When additives (e.g., a photoacid generator (PAG) or any herein) are used, the temperature for removal can be between about 50° C. and about 125° C., in addition to exposure to other stimulus that can beneficially activate the additive (e.g., UV exposure to activate the PAG).

For basic thermal removal of surface protection films (e.g., providing a substrate on a hot plate), exposure time can be from about 20 seconds to about 400 seconds (e.g., about 30 to 300 seconds). Thicker films can require longer exposure to heat for SRP removal, as compared to thinner films. Film thickness required will be application dependent. For instance, some removal thermal processes (e.g., using a rapid thermal processor (RTP)) can include higher temperatures (e.g., more than about 400° C.) for very short times (e.g., one to two seconds of exposure for RTP, as well as millisecond exposure times for flash lamp type processes). For applications that are thermal budget sensitive, RTP-type conditions can be employed, whereas other processes may employ a hot plate under vacuum.

Alternatively, the SRP can be removed by exposure to radiation (e.g., UV radiation or IR radiation), either with or without vacuum, in an operation 303. In some instances, process conditions include exposure to about 400° C. under vacuum at about 2.5 W/cm² UV dose rate. In other instances, process conditions (e.g., for an SRP employed with a photoacid generator) includes exposure to about 110° C. under vacuum for at about 0.05 mW/cm² UV dose rate. In any of these process conditions, exposure can include from about 100 seconds to about 400 seconds (e.g., about 300 seconds).

For radiation removal of surface protection films (e.g., pure SRP), exposure time can be from about 20 seconds to about 400 seconds (e.g., about 30 to 300 seconds). Thicker films can require longer exposure to radiation (e.g., UV) for SRP removal, as compared to thinner films. Film thickness required will be application dependent. For films with acid generating additives (e.g., PAG), the exposure times may range from two minutes to ten minutes. Exposure time can depend on many conditions, including the loading of the additives, wafer temperature, UV dose rate, and film thickness. These requirements, in turn, will be application dependent (e.g., depend on feature dimensions, aspect ratio, pattern density, etc.).

Radiation dosage can be, e.g., from about 0.1 mW/cm² to about 15 W/cm² for UV. For bracing applications in which rate control of the degradation can be desired, lower dose rates can be employed, e.g., from about 0.01 to about 0.07 mW/cm². For pure SRP film removal from blanket surfaces, higher dose rates can be employed, e.g., about 2.5 W/cm². Generally, the higher the dose rate, the cleaner the removal. Of course, radiation exposure can also be application dependent, and excessive radiation can be avoided to mitigate substrate damage.

During radiation exposure, the substrate can be maintained at an elevated temperature (e.g., from about 300° C. to about 500° C., including about 400° C.). When the formulation includes acid generating additives (e.g., PAG), then lower temperatures can be combined with UV exposure to provide a controlled degradation rate (e.g., temperature range of about 50° C. to about 125° C. or from about 100° C. to about 110° C.).

Metastable atoms are employed in another operation 304. The metastable atoms can be generated from a noble gas plasma, the noble gas being one or more of helium (He), neon (Ne), argon (Ar), krypton (Kr), and xenon (Xe), to remove residue from the substrate. In some embodiments, the metastable species are not chemically reactive and do not appreciably affect the underlying surface. The metastable species from the noble gas plasma can be effective at removing residues that remain after exposure to other stimuli such as heat.

In the methods described herein, removing SRPs includes exposure to high energy metastable species, generated in a noble gas plasma, at an elevated temperature. The metastable species have sufficient energies and lifetimes to scission bonds on the polymer or other residues. At temperatures greater than the ceiling temperature, there is a strong thermodynamic driving force to revert to volatile monomers once bond scissioning has occurred. The metastable species are not chemically reactive and do not appreciably affect the underlying surface. The metastable species are effective at removing residue that remains after exposure to other stimuli such as heat. This residue may be some SRP that remains polymerized or cross-linked and/or carbonized shards that is detectable by ellipsometry. While most of the SRP can be removed by the stimuli described above, this residue can be difficult to fully remove by those methods. Without being bound by a particular theory, the metastables may remove residues by re-initiating chain scissioning that may have stopped prematurely due to side product formation, by breaking down char that may have formed during the depolymerization process, and by aiding monomer desorption.

In some embodiments, most of the SRP is removed before exposing the substrate to the metastable atoms. In some embodiments, the substrate is exposed to the metastable atoms before most of the SRP is removed. In some embodiments, the plasma pressure is between about 10 mTorr to 10 Torr. In some embodiments, the plasma pressure is between about 100 mTorr and 1 Torr. In some embodiments, the SRP is provided between HAR structures. In some embodiments, the SRP is provided as a protective coating on substrate. In some embodiments, the plasma is generated in an inductively coupled plasma (ICP) source. In some such embodiments, the ICP source is separated from the substrate by a showerhead or other filter. In some embodiments, the plasma is generated in capacitively coupled plasma (CCP) source. Any other type of plasma source may be used. In some embodiments, exposing the substrate to a stimulus and exposing the substrate to the metastable atoms are performed in the same chamber.

Processing and plasma source chamber pressure may be used to control the plasma-based removal. Pressure is important to control the density of the metastable atoms. If pressure is too low, the density of metastable atoms may not be high enough to efficiently clean the surface. If the pressure is too high, metastable species may be lost to collisions. Example pressures may range from 10 mTorr to 10 Torr, 100 mTorr to 1 Torr, 100 mTorr to 700 mTorr, 200 mTorr to 1 Torr, or 200 mTorr to 2 Torr.

Substrate temperature and plasma power may also be used to control removal. Temperature is high enough such that it is above the ceiling temperature of the polymer. Higher temperatures aid removal with the maximum temperature limited by the thermal budget of the device or other materials on the substrate. Example temperatures may range from 150° C. to 1000° C. or from 150° C. to 400° C. Plasma power is high enough to generate metastable atoms. Example powers may range from 500 W to 5000 W or from 800 W to 5000 W, e.g., 2500 W for a 300 mm wafer, and scale linearly with substrate area. Example exposure times may range from 10 seconds to 300 seconds or from 10 seconds to 180 seconds.

As seen in FIG. 3A, yet other conditions include exposure to acidic or basic vapors in an operation 305 or exposure to plasma in an operation 306. Such vapors can be provided by a reactant, such as an acid (e.g., having a pKa of less than 7, and in some embodiments less than 4, or less than 2) or a base (e.g., having a pKb of less than 7, and in some embodiments, less than 4 or less than 2). Non-limiting reactants include sulfurous acid, nitric acid, carbonic acid, or ammonium hydroxide.

A catalyst can be used with the acid, base, or a reactant that forms the acid or base. Non-limiting catalysts include hydrogen bromide (HBr), hydrogen chloride (HCl), hydrogen fluoride (HF), hydrogen iodide (HI), nitric acid (HNO₃), formic acid (CH₂I₂), acetic acid (CH₃COOH), formonitrile (HCN), sulfurous acid (H₂SO₃), carbonic acid (H₂CO₃), nitrous acid (HNO₂), or ammonia (NH₃), and methyl or ethyl amine gas or vapor may be used. In some examples, when HBr vapor is used, the substrate is maintained at a pressure in a range from 1 mTorr to 5000 mTorr (e.g., from 5 mTorr to 5000 mTorr) and a temperature in a range from 0° C. to 200° C. (e.g., from 0° C. to 100° C.). In some examples, the substrate is maintained at a pressure in a range from 750 mTorr to 1500 mTorr and a temperature in a range from 35° C. to 70° C. In some examples, the temperature of the substrate is maintained at a pressure of 1000 mTorr and a temperature of 60° C. The amount of acidic vapor or vapor of other compound is controlled to limit the diffusion. Exposure time can depend on the strength of the acid or base, as well as film thickness and exposure temperature (e.g., from about 20° C. to about 125° C. or from about 100° C. to about 125° C.). Non-limiting exposure time can include less than about 60 seconds or on the order of minutes.

Removal can occur in a single step or in a plurality of steps. As seen in FIG. 3B, a method 320 can include providing a substrate with an SRP film in an operation 321. Then, a stimulus that degrades SRP is pulsed in the chamber in an operation 323. Such stimulus can include exposure to a compound (e.g., an acid, a base, a compound that forms an acid or base, plasma, metastable compounds, etc.) or a reaction condition (e.g., UV radiation, IR radiation, heat, etc.). In some embodiments, removal includes exposure to heat and/or radiation, thus eliminating the need for plasma and/or harsh wet chemistries that will modify the sensitive surfaces that need to be protected.

When a compound is used, the partial pressure of the vapor and/or the pulse time can be controlled to control the overall exposure to the vapor and the diffusion depth. The chamber can be purged in an operation 325. Purging can involve evacuating the chamber and/or flowing inert gas to be swept out through the chamber. Such a gas may be, for example, continuously flowing including during operation 323 or may be itself pulsed into the chamber. During operation 325, volatilized monomer or SRP fragment may be pumped or purged out of the chamber. Operations 323 and 325 are repeated until the SRP is removed in an operation 327. As indicated above, in some embodiments, the SRP is exposed to reactants sequentially in each cycle. This can provide additional control over the process and may be implemented in various ways.

In other embodiments, removal can include exposure to two reactants that react to form an acid or base that can trigger the degradation of the SRP. The exposure occurs sequentially to provide more precise top down control. In some embodiments, the methods involve diffusing a compound, or a reactant that reacts to form a compound, only to a top portion of the SRP. The top portion is then degraded and removed, leaving the remaining SRP intact. The exposure and removal cycles can be repeated. Optionally, a purge operation can follow the exposure operation to remove the compound or reactant from the chamber.

Non-limiting reactants (e.g., to form an acid or base) can include water vapor with one of ammonia (NH₃) or a gaseous oxide, which reacts with the water vapor to an acidic or basic species. For instance, NH3 and water can react to form ammonium hydroxide (NH₄OH). Examples of gaseous oxides include nitrogen dioxide (NO₂, which can react with water to form nitric acid, HNO₃), sulfur dioxide (SO₂, which can react with water to form sulfurous acid, H₂SO₃), and carbon dioxide (CO₂, which can react with water to form carbonic acid, H₂CO₃). Other oxides may react with water or another reactant to form acids or bases.

According to various embodiments, the reaction may be catalyzed or uncatalyzed. In some embodiments, a catalyst (e.g., a thermally activated catalyst) may be provided in the SRP, delivered with a reactant, or introduced as a separate pulse. However, in many embodiments, the reaction is uncatalyzed such that SRP is provided free of catalysts. This can facilitate SRP removal. In some embodiments, the reaction is byproduct-free.

Additional examples of SRPs and methods using SRPs are described in U.S. Pat. Nos. 9,466,511, 9,666,427, 10,008,396, and 10,068,781, each of which are incorporated herein by reference in its entirety.

### SRPs

In many embodiments, the SRPs are low ceiling temperature (T_{c}) polymers. T_{c} is the equilibrium temperature between a polymer and its monomers. As used herein, the term low T_{c} refers to T_{c} values below a removal temperature. In some embodiments, the T_{c} is below room temperature, such that the polymers are thermodynamically unstable at room temperature. Instead, the low T_{c} polymer is kinetically trapped to allow prolonged storage at room temperature. In some examples, the stable storage period is on the order of months or years. Low T_{c} polymers will rapidly de-polymerize to its monomer constituents if an end-group or main chain bond is broken. Thus, the polymer de-polymerizes in response to stimuli such as ultraviolet (UV) light, heat, thermal catalyst, photocatalyst, or an acidic/basic catalyst. The monomer products are volatile and leave or can be easily removed from the surface and chamber.

While in some embodiments, the T_{c} is below room temperature, in the context of semiconductor processing, low T_{c} may also refer to ceiling temperatures that are higher than room temperature. For example, removal temperatures of up to 400° C. may be used, meaning that the ceiling temperature is below 400° C.

Example of SRPs are provided below. However, the methods described herein may be used with any SRPs. In some embodiments, the SRPs are homopolymers including poly(aldehydes). In particular embodiments, they may be self-immolative polymers as described in U.S. Patent Publication No. 2018/0155483, which was published on Jun. 7, 2018 and which is hereby incorporated herein by reference in its entirety.

SRPs can be any appropriate homopolymer in linear or cyclic form. Non-limiting SRPs include a poly(phthalaldehyde), a poly(aldehyde), a poly(benzyl carbamate), a poly(benzyl ether), a poly(alpha-methyl styrene), a poly(carbonate), a poly(norbornene), a poly(olefin sulfone), a poly(glyoxylate), a poly(glyoxylamide), a poly(ester), or a poly(methyl methacrylate), as well as derivatives thereof. Such derivatives can include replacement of oxy (—O—) with an optionally substituted heteroalkylene, as defined herein, as well as substitutions with one or more substitution groups, as described herein for alkyl.

Yet other SRPs can include those having a structure of one of formulas (I)-(XV), (Ia), (Ib), or (Ic). Such SRPs can be a linear polymer or a cyclic polymer. If linear, the polymer can include any useful end groups that terminate the molecule. Such end groups can depend on the reactive end groups present on the monomers employed to synthesize the polymer. In particular embodiments, end groups can include those fragments formed from use of an anionic initiator (e.g., fragments such as alkyl anion, e.g., present in n-BuLi, s-BuLi, etc.), from use of an acylation or alkylation reagent (e.g., fragments such as acyl or optionally substituted alkanoyl, such as formyl, acetyl, benzoyl, methyl, ethyl, etc.), from use of a conjugated alkylene monomer (e.g., such as a quinone methide monomer), or from use of an alcohol termination agent (e.g., fragments such as optionally substituted alkoxy). The end groups can include any useful binding group or a reactive group (e.g., those including optionally substituted trialkylsiloxy, optionally substituted alkenyl, optionally substituted aryl, etc.).

The SRP can include a poly(phthalaldehyde) or a derivative thereof, which can be a homopolymer that is linear or cyclic. In one embodiment, the SRP is or includes a structure of formula (I):

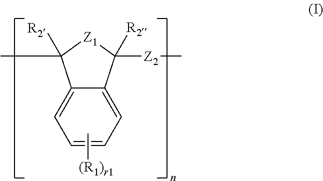

or a salt thereof, wherein
each R₁ is, independently, H, optionally substituted alkyl, optionally substituted alkoxy, optionally substituted alkenyl, optionally substituted aryl, or halo;
each of R_{2′} and R_{2″} is, independently, H, optionally substituted alkyl, optionally substituted heteroalkyl, or optionally substituted aryl;
each of Z₁ and Z₂ is, independently, —O—, —S—, or optionally substituted heteroalkylene;
r1 is an integer from 1 to 4; and
n is from about 2 to about 100,000.

In particular embodiments (e.g., of formula (I)), each of R_{2′} and R_{2″} is, independently, H or optionally substituted alkyl. In some embodiments, each of Z₁ and Z₂ is —O—.

The SRP can include a poly(aldehyde) or a derivative thereof, which can be a homopolymer that is linear or cyclic. In one embodiment, the SRP is or includes a structure of formula (II):

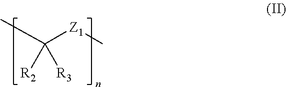

or a salt thereof, wherein:
each of R₂ and R₃ is, independently, H, optionally substituted alkyl, optionally substituted heteroalkyl, or optionally substituted aryl;
Z₁ is —O—, —S—, or optionally substituted heteroalkylene; and
n is from about 2 to about 100,000.

The SRP can include a poly(benzyl carbamate) or a derivative thereof, which can be a homopolymer that is linear or cyclic. In one embodiment, the SRP is or includes a structure of formula (III):

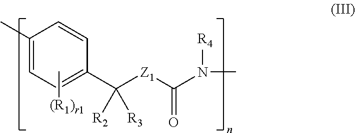

or a salt thereof, wherein:
each R₁ is, independently, H, optionally substituted alkyl, optionally substituted alkoxy, optionally substituted alkenyl, optionally substituted aryl, or halo;
each of R₂ and R₃ is, independently, H, optionally substituted alkyl, optionally substituted heteroalkyl, or optionally substituted aryl;
R₄ is H or optionally substituted alkyl;
Z₁ is —O—, —S—, or optionally substituted heteroalkylene;
r1 is an integer from 1 to 4; and
n is from about 2 to about 100,000.

In particular embodiments (e.g., of formula (III)), R₁ is optionally substituted alkoxy. In other embodiments, n is from about 2 to about 100 (e.g., from about 2 to 10, 2 to 15, 2 to 20, 2 to 25, 2 to 30, 2 to 40, 2 to 50, 2 to 75, 4 to 10, 4 to 15, 4 to 20, 4 to 25, 4 to 30, 4 to 40, 4 to 50, 4 to 75, and 4 to 100).

The SRP can include a poly(benzyl ether) or a derivative thereof, which can be a homopolymer that is linear or cyclic. In one embodiment, the SRP is or includes a structure of formula (IV):

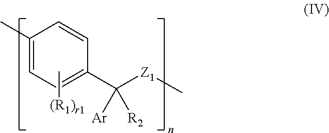

or a salt thereof, wherein:
each R₁ is, independently, H, optionally substituted alkyl, optionally substituted alkoxy, optionally substituted alkenyl, optionally substituted aryl, or halo;
R₂ is H, optionally substituted alkyl, optionally substituted heteroalkyl, or optionally substituted aryl;
Ar is optionally substituted aryl, optionally substituted alkyl, or optionally substituted aralkyl;
Z₁ is —O—, —S—, or optionally substituted heteroalkylene;
r1 is an integer from 1 to 4; and
n is from about 2 to about 100,000.

In particular embodiments (e.g., of formula (IV)), R₁ is optionally substituted alkyl. In other embodiment, Ar is optionally substituted phenyl. In other embodiments, n is from about 2 to about 5000.

The SRP can include a poly(benzyl dicarbamate) or a derivative thereof, which can be a homopolymer that is linear or cyclic. In one embodiment, the SRP is or includes a structure of formula (V):

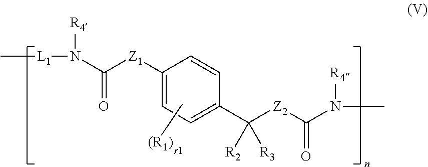

or a salt thereof, wherein:
each R₁ is, independently, H, optionally substituted alkyl, optionally substituted alkoxy, optionally substituted alkenyl, optionally substituted aryl, or halo;
each of R₂ and R₃ is, independently, H, optionally substituted alkyl, optionally substituted heteroalkyl, or optionally substituted aryl;
each of R_{4′} and R_{4″} is, independently, H or optionally substituted alkyl;
L₁ is optionally substituted alkylene, optionally substituted heteroalkylene, optionally substituted arylene, or optionally substituted cycloalkylene;
each of Z₁ and Z₂ is, independently, —O—, —S—, or optionally substituted heteroalkylene;
r1 is an integer from 1 to 4; and
n is from about 2 to about 100,000.

In particular embodiments (e.g., of formula (V)), R₁ is optionally substituted alkyl. In other embodiment, Ar is optionally substituted phenyl. In other embodiments, n is from about 2 to about 5000. In other embodiments (e.g., of formula (V)), each of R_{4′} and R_{4″} is, independently, optionally substituted alkyl. In some embodiments, L₁ is optionally substituted alkylene. In other embodiments, Z₁ and Z₂ is —O—.

The SRP can include a poly(dicarbamate) or a derivative thereof, which can be a homopolymer that is linear or cyclic. In one embodiment, the SRP is or includes a structure of formula (VI):

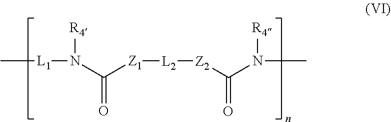

or a salt thereof, wherein:
each of R_{4′} and R_{4″} is, independently, H or optionally substituted alkyl;
each of L₁ and L₂ is, independently, optionally substituted alkylene, optionally substituted heteroalkylene, optionally substituted arylene, or optionally substituted cycloalkylene, in which L₂ can optionally be a covalent bond;
each of Z₁ and Z₂ is, independently, —O—, —S—, or optionally substituted heteroalkylene; and
n is from about 2 to about 100,000.

In particular embodiments (e.g., of formula (VI)), each of R_{4′} and R_{4″} is, independently, optionally substituted alkyl. In some embodiments, each of L₁ and L₂ is, independently, optionally substituted alkylene. In other embodiments, each of Z₁ and Z₂ is, independently, —O— or —S—.

The SRP can include a poly(alpha-methyl styrene) or a derivative thereof, which can be a homopolymer that is linear or cyclic. In one embodiment, the SRP is or includes a structure of formula (VII):

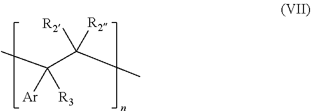

or a salt thereof, wherein:
each of R_{2′}, R_{2″}, and R₃ is, independently, H, optionally substituted alkyl, optionally substituted heteroalkyl, or optionally substituted aryl;
Ar is optionally substituted aryl, optionally substituted alkyl, or optionally substituted aralkyl; and
n is from about 2 to about 100,000.

The SRP can include a poly(carbonate) or a derivative thereof, which can be a homopolymer that is linear or cyclic. In one embodiment, the SRP is or includes a structure of formula (VIII):

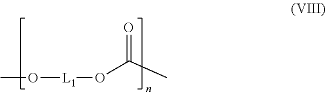

or a salt thereof, wherein:
L₁ is optionally substituted alkylene, optionally substituted heteroalkylene, optionally substituted arylene, or optionally substituted cycloalkylene; and
n is from about 2 to about 100,000.

In particular embodiments (e.g., of formula (VIII)), L₁ is optionally substituted alkylene, optionally substituted heteroalkylene, or optionally substituted cycloalkylene. In some embodiments, the optionally substituted heteroalkylene is —X-Ak-X—, in which X is oxy and Ak is optionally substituted alkylene. Non-limiting SRPs can include poly(ethylene carbonate), poly(propylene carbonate) (PPC), poly(butylene carbonate) (PBC), poly(cyclohexene carbonate) (PCHC), poly(norbornene carbonate) (PNC), and poly(cyclohexene propylene carbonate) (PCPC).

The SRP can include a poly(norbornene) or a derivative thereof, which can be a homopolymer that is linear or cyclic. In one embodiment, the SRP is or includes a structure of formula (IX):

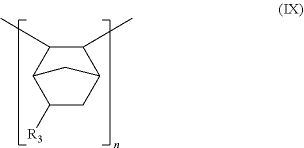

or a salt thereof, wherein:
R₃ is H, optionally substituted alkyl, optionally substituted heteroalkyl, or optionally substituted aryl; and
n is from about 2 to about 100,000.

The SRP can include a poly(olefin sulfone) or a derivative thereof, which can be a homopolymer that is linear or cyclic. In one embodiment, the SRP is or includes a structure of formula (X):

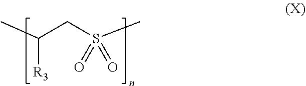

or a salt thereof, wherein:
R₃ is H, optionally substituted alkyl, optionally substituted heteroalkyl, or optionally substituted aryl; and
n is from about 2 to about 100,000.

In particular embodiments (e.g., of formula (X)), R₃ is optionally substituted heteroalkyl, such as, e.g., —OC(O)—R^{O1}, —NR^{N1}—C(O)—R^{O1}, —OC(O)NR^{N1}R^{N2}, -(Ak-O)ₕ₁R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl (e.g., hydroxyalkyl, carboxyalkyl, aminoalkyl, or azidoalkyl).

The SRP can include a poly(glyoxylate) or a derivative thereof, which can be a homopolymer that is linear or cyclic. In one embodiment, the SRP is or includes a structure of formula (XI):

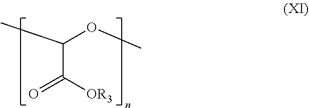

or a salt thereof, wherein:
R₃ is H, optionally substituted alkyl, optionally substituted heteroalkyl, or optionally substituted aryl; and
n is from about 2 to about 100,000.

In particular embodiments (e.g., of formula (XI)), R₃ is optionally substituted alkyl or optionally substituted heteroalkyl, such as, e.g., -(Ak-O)ₕ₁R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl.

The SRP can include a poly(methyl methacrylate) or a derivative thereof, which can be a homopolymer that is linear or cyclic. In one embodiment, the SRP is or includes a structure of formula (XII):

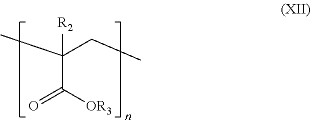

or a salt thereof, wherein:
each of R₂ and R₃ is, independently, H, optionally substituted alkyl, optionally substituted heteroalkyl, or optionally substituted aryl; and
n is from about 2 to about 100,000.

In particular embodiments (e.g., of formula (XII)), R₂ is optionally substituted alkyl. In other embodiments (e.g., of formula (XII)), R₃ is optionally substituted alkyl or optionally substituted heteroalkyl, such as, e.g., -(Ak-O)ₕ₁R^{O1} or -Ak-NR^{N1}R^{N2}, in which Ak is optionally substituted alkylene, hl is from 1 to 5, and each of R^{O1}, R^{N1}, and R^{N2} is, independently, H or optionally substituted alkyl.

The SRP can include a poly(glyoxylamide) or a derivative thereof, which can be a homopolymer that is linear or cyclic. In one embodiment, the SRP is or includes a structure of formula (XIII):

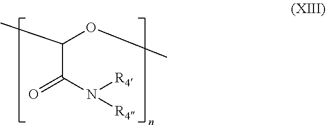

or a salt thereof, wherein:
each of R_{4′} and R_{4″} is, independently, H, optionally substituted alkyl, optionally substituted aminoalkyl, optionally substituted heteroalkyl, or R_{4′}, and R_{4″}, taken together with the nitrogen atom to which each are attached, form a heterocyclyl group, as defined herein; and
n is from about 2 to about 100,000.

In particular embodiments (e.g., of formula (XIII)), each of R_{4′} and/or R_{4″} is optionally substituted alkyl, optionally substituted heteroalkyl, or optionally substituted aminoalkyl, such as, e.g., -(Ak-O)₁R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl. In other embodiments, R_{4′} is H or alkyl, and R_{4″} is optionally substituted alkyl, optionally substituted heteroalkyl, or optionally substituted aminoalkyl (e.g., as described above). In yet other embodiment, R_{4′}, and R_{4″}, taken together with the nitrogen atom to which each are attached, form a heterocyclyl group, as defined herein. Non-limiting heterocyclyl groups include pyrrolidinyl, piperidinyl, morpholinyl, oxazolyl, isoxazolyl, pyrrolyl, pyrazolyl, and the like.

As can be seen in formula (I) and (II), the SRP can be a poly(aldehyde), including poly(phthalaldehyde) or a generic poly(aldehyde) with a backbone consisting of alternating carbon and oxygen, including poly(oxymethylene). Such SRPs can be a linear or a cyclic homopolymer. The SRP can be a poly(phthalaldehyde) or a derivative thereof, such as a polymer including a structure of formula (Ia):

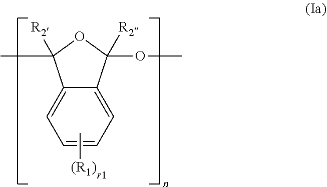

or a salt thereof, for any R₁, R_{2′}, R_{2″}, r1, and n described herein. In some instances, n is an integer from 4 to 100,000.

In other embodiments, the poly(phthalaldehyde) is cyclic. In some instances, the polymer has structure of formula (Ib) or (Ic):

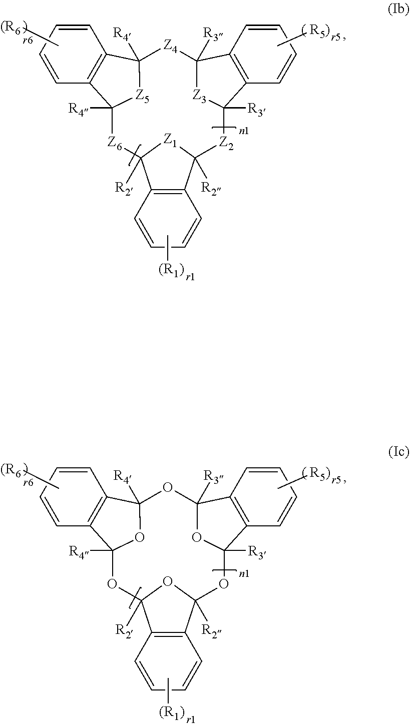

or a salt thereof, or any R₁, R₅, R₆, R_{2′}, R_{2″}, R_{3′}, R_{3″}, R_{4′}, R_{4″}, Z₁, Z₂, Z₃, Z₄, Z₅, Z₆, r1, r5, r6, and n1 described herein. In some instances, n1 is an integer from 1 to 100.

In any embodiment herein (e.g., in formula (I)-(VI) and (Ib)), each of Z₁ to Z₆, L₁, and L₂, if present, is, independently, an optionally substituted heteroalkylene selected from —CR₂R₃O—, —OCR₂R₃—, —OCR₂R₃O—, —(CR₂R₃S)ₕ₁CR₂R₃—, —S(CR₂R₃S)ₕ₁—, —CR₂R₃S—, —SCR₂R₃—, —SCR₂R₃S—, —(CR₂R₃S)ₕ₁CR₂R₃—, and —S(CR₂R₃S)ₕ₁—, in which each of R₂ and R₃ is, independently, H, optionally substituted alkyl, or optionally substituted aryl, and h1 is an integer from 1 to 5. In other embodiments, each of Z₁ to Z₆, L₁, and L₂, if present, is, independently, —O— or an optionally substituted heteroalkylene.

In any embodiment herein (e.g., in formula (I)-(V), (VII), and (XII)), each of R₂, R_{2′}, and R_{2″}, if present, is, independently, H or optionally substituted alkyl (e.g., C₁₋₆ alkyl).

In any embodiment herein (e.g., in formula (II), (III), (V), (VII), (IX), (X), (XI), and (XII)), R₃ is optionally substituted aryl.

In any embodiment herein (e.g., in formula (II), (III), (V), (VII), (IX), (X), (XI), and (XII)), R₃ is optionally substituted heteroalkyl, such as, e.g., —OC(O)—R^{O1}, —NR^{N1}—C(O)—R^{O1}, —OC(O)NR^{N1}R^{N2}, -(Ak-O)ₕ₁R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl (e.g., hydroxyalkyl, carboxyalkyl, aminoalkyl, or azidoalkyl).

In any embodiment herein, the polymer is a homopolymer. Such a polymer can have any useful number n of monomers, such as n is from about 2 to about 100,000 (e.g., about 2 to 50, 2 to 100, 2 to 200, 2 to 300, 2 to 400, 2 to 500, 2 to 1,000, 2 to 2,000, 2 to 5,000, 2 to 10,000, 2 to 20,000, 2 to 50,000, 2 to 100,000, 3 to 50, 3 to 100, 3 to 200, 3 to 300, 3 to 400, 3 to 500, 3 to 1,000, 3 to 2,000, 3 to 5,000, 3 to 10,000, 3 to 20,000, 3 to 50,000, 3 to 100,000, 4 to 50, 4 to 100, 4 to 200, 4 to 300, 4 to 400, 4 to 500, 4 to 1,000, 4 to 2,000, 4 to 5,000, 4 to 10,000, 4 to 20,000, 4 to 50,000, 4 to 100,000, 5 to 50, 5 to 100, 5 to 200, 5 to 300, 5 to 400, 5 to 500, 5 to 1,000, 5 to 2,000, 5 to 5,000, 5 to 10,000, 5 to 20,000, 5 to 50,000, 5 to 100,000, 10 to 50, 10 to 100, 10 to 200, 10 to 300, 10 to 400, 10 to 500, 10 to 1,000, 10 to 2,000, 10 to 5,000, 10 to 10,000, 10 to 20,000, 10 to 50,000, 10 to 100,000, 50 to 100, 50 to 200, 50 to 300, 50 to 400, 50 to 500, 50 to 1,000, 50 to 2,000, 50 to 5,000, 50 to 10,000, 50 to 20,000, 50 to 50,000, 50 to 100,000, 100 to 200, 100 to 300, 100 to 400, 100 to 500, 100 to 1,000, 100 to 2,000, 100 to 5,000, 10 to 10,000, 100 to 20,000, 100 to 50,000, and 100 to 100,000). In other embodiments, the polymer is cyclic, in which n is from about 3 to about 100. In other embodiments, the cyclic polymer includes any useful number n1+2 of monomers, such as n1 from about 1 to about 100.

In particular embodiments, the SRPs may also be any appropriate linear or cyclic copolymer including the pure phthalaldehyde homopolymer, a homopolymer of poly(phthalaldehyde) derivatives such as poly(4,5-dichlorophthalaldehyde), or a homopolymer of poly(aldehyde) derivatives. SRPs can include a copolymer including a structure of one of formulas (I)-(XIII), (Ia), (Ib), (Ic), or a salt thereof, as well as any copolymer described herein (e.g., one of formulas (XIV) or (XV)).

Further example of SRPs are provided below. In some embodiments, the SRPs are copolymers including poly(aldehydes). In particular embodiments, they may be self-immolative polymers as described in U.S. Patent Publication No. 2018/0155483, which was published on Jun. 7, 2018 and which is hereby incorporated herein by reference in its entirety. Examples of copolymers in that reference include those of Formula (XIV):

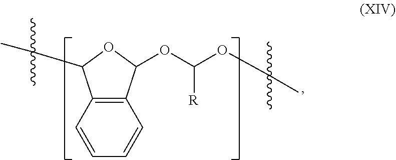

wherein:
R is substituted or unsubstituted C₁₋₂₀ alkyl, C₁₋₂₀ alkoxy, C₂₋₂₀ alkenyl, C₂₋₂₀ alkynyl, C₆₋₁₀ heteroaryl, C₃₋₁₀ cycloalkyl, C₃₋₁₀ cycloalkenyl, C₃₋₁₀ heterocycloalkyl, or C₃₋₁₀ heterocycloalkenyl; and, when substituted, R is substituted with C₁₋₂₀ alkyl, C₁₋₂₀ alkoxy, C₂₋₂₀ alkenyl, C₂₋₂₀ alkynyl, C₆₋₁₀ aryl, C₆₋₁₀ heteroaryl, carboxyaldehyde, amino, sulfonic acid, sulfinic acid, fluoroacid, phosphonic acid, ether, halo, hydroxyl, ketone, nitro, cyano, azido, silyl, sulfonyl, sulfinyl, or thiol.

In particular embodiments, the SRPs are cyclic copolymers of the phthalaldehyde monomer with a second aldehyde such as ethanal, propanal, or butanal. Examples of such copolymers are given in U.S. Patent Publication No. 2018/0155483 as Formula (XV):

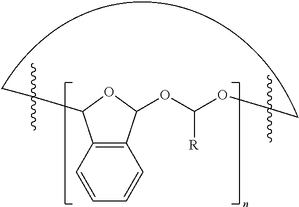

(XV), wherein n is an integer from 1 to 100,000 and R can be any described herein (e.g., such as for Formula (XIV)).

Specific examples in U.S. Patent Publication No. 2018/0155483 include copolymers of phthalaldehyde and one or more of acetaldehyde, propanal, butanal, pentanal, hexanal, heptanal, octanal, nonanal, decanal, undecanal, propenal, butenal, pentenal, hexenal, heptenal, octenal, nonenal, decenal, undecenal, and any combination thereof.

The SRPs may also be any appropriate linear or cyclic copolymer including the pure phthalaldehyde homopolymer. It also may be a homopolymer of poly(phthalaldehyde) derivatives such as poly(4,5-dichlorophthalaldehyde).

In other embodiments, the SRP is a homopolymer possessing a low MW, thereby providing a low viscosity polymer for filling gaps.

In any embodiment herein, the SRP includes a monomer that is or has a structure of any of formulas (I)-(XV), (Ia), or a salt thereof, in which n is 1, which is then linked to another monomer by way of a linker. Non-limiting linkers include optionally substituted alkylene, optionally substituted heteroalkylene, optionally substituted (aryl)(alkyl)ene, optionally substituted arylene, optionally substituted cycloalkylene, oxy, or thio. In other embodiments, the linker can be -Ak-, -Ak-X—, —X-Ak-, -(Ak-X)ₕ₁-Ak-, —X-(Ak-X)ₕ₁—, -Ak-Ar—, -Ak-Ar-Ak-, —Ar-Ak-, -(Ak-X)ₕ₁—Ar—, -(Ak-X)ₕ₁—Ar-(Ak-X)ₕ₁—, —Ar-(Ak-X)ₕ₁—, —X-(Ak-X)ₕ₁—Ar—, —X-(Ak-X)₁—Ar—X-(Ak-X)ₕ₁—, and —Ar—X-(Ak-X)ₕ₁—, in which Ak is an optionally substituted alkylene, Ar is an optionally substituted arylene, X is or includes a non-carbon heteroatom (e.g., —O—, —S—, or —NR^{N1}—, which R^{N1} is H, optionally alkyl, or optionally substituted aryl), and hl is an integer from 1 to 5.

In any embodiment herein, the SRP can be an amorphous polymer that remains solvent soluble.

The SRP can be synthesized using any corresponding monomer. For instance, the monomer can be or have a structure of any of formulas (I)-(XV), (Ia), or a salt thereof, in which n is 1. The monomer can have any useful end group disposed on either end of such a structure. In other embodiments, the monomer can be volatile and possess a melting point at or below 20° C.

In particular embodiments, the SRP is formed with no unwanted side products. In this way, residue-free vaporization of the polymer can be achieved because side products need not be removed. For removal, scission of one (or few) chemical bonds within the SRP propagates full, rapid depolymerization of the polymer. Since all the bonds are the same (no inadvertent impurities), little or no residue is expected.

The SRP, or a formulation thereof, can be deposited in any useful manner. For instance, the SRP can be spin-coated or vapor deposited.

### Formulations, Including Solvents and Additives

The SRP can be provided as a formulation having a solvent or a solvent combination. In one embodiment, the formulation includes about 0.1 wt. % to about 50 wt. % of one or more SRPs (e.g., about 5 wt. % to 20 wt. %), with the balance being the solvent. Example solvents include diglyme, tetrahydrofuran, N-methyl-pyrrolidone, dimethylformamide, propylene carbonate, cyclopentanone, anisole, dichlorobenzene, and propylene glycol methyl ether acetate.

Formulations can include one or more further additives selected from a plasticizer, an organic acid having a pKa more than or equal to 1, a photocatalyst (e.g., a photoacid generator or a photobase generator), a thermal catalyst (e.g., a thermal acid generator or a thermal base generator), and/or a dye. The amount of additive can include about 0.001 wt. % to about 25 wt. % of a single additive, as well as a combination of additives in an amount of about 0.001 wt. % to about 25 wt. %.

In some embodiments, the SRP and the additive(s) (e.g., any herein) may be formulated and stored as separate solutions but mixed together at point of deposition onto the wafer, or at some point relatively shortly beforehand. In some embodiments, the SRP and additive(s) may be provided as a powder to be mixed in the solvent before spin coating. The SRP and additive (either singularly or together) may be provided with a relative wt. % of at least 5:1 SRP: additive, or at least 10:1, or 20:1.

Plasticizers can be employed to promote plasticity or flexibility in the film. Non-limiting plasticizers can include adipates, alkylene glycol dibenzoates, dialkyl phthalates, trialkyl trimellitates, tertiary amines, quaternary ammonium compounds, azelates, citrates, ether-esters, polyethers, glutarates, glycols, isobutyrates, maleates, phosphates, phosphonium compounds, organophosphates, sebacates, sulfonamides, sulfonium compounds, as well as ionic liquids, surfactants, and acid amplifiers, or a combination thereof.

The low T_{c} homopolymers can be formulated with weak acids that create stable films under ambient conditions, as well as exhibit accelerated degradation characteristics, as compared to the neat, unformulated homopolymer in a solvent. Specific examples of acids with this behavior include weak organic acids (e.g., having a pKa that is more than or equal to 1). Yet other acids include tartaric acid, oxalic acid, and acetic acid.

Other examples include linear alkyl carboxylic acids, C_{X}H_{2X}O₂, where X is an integer, and the corresponding dicarboxylic acid variants. Particular examples include including methanoic acid (X=1) and acetic acid (X=2). Particular examples of dicarboxylic acids include ethanedioic acid and propanedioic acid. The organic weak acid may also be variants of any of these with additional alcohol substitutions and/or unsaturated bonds. For example, oxoethanoic acid, 2-hydroxyethanoic acid, prop-2-enoic acid, 2-propynoic acid, 2-hydroxypropanedioic acid, oxopropanedioic acid, 2,2-dihydroxypropanedioic acid, 2-oxopropanoic acid, 2-hydroxypropanoic acid, 3-hydroxypropanoic acid, 2,3-dihydroxypropanoic acid, etc., may be used.

Yet other organic acids could exhibit similar abilities. The low T_{c} homopolymer may be pre-formulated with the appropriate acid prior to tool installation, and then spin-coated onto the substrates for sacrificial bracing or surface protection applications. Alternatively, the low T_{c} polymer may be mixed with the acid at point of use, right before spin-coating. This approach may be used to prolong the shelf-life of the homopolymer formulation, since although it is stable in film form (solid state), it may not be stable in solution once contacted with the acid. In some embodiments, the formulation is provided as about 5-20 wt. % SRP and <1 wt. % organic weak acid, with the balance being the solvent.

The formulation, and thus the resultant film, can include a photoacid generator (PAG), in which exposure of the SRP to electromagnetic radiation produces acid. In this way, energetic light (e.g., UV light, IR lights, or x-rays) exposure generates acid to promote in situ degradation of the film. Non-limiting photoacid generators include onium salts, such as iodonium and sulfonium salts having perfluorinated anions (e.g., diaryliodonium and triarylsulfonium salts), bissulfonyldiazomethane compounds, N-sulfonyloxydicarboximide compounds, and O-arylsulfonyloxime compounds. The photoacid generator may optionally include a photosensitizer (e.g., having modified polyaromatic hydrocarbons or fused aromatic rings).

Other acid generators can be used, such as a thermal acid generator that releases acidic moieties upon exposure to heat. In this way, depolymerization of the SRP can include both thermal and acidic processes. Non-limiting thermal acid generators include ammonium salts, sulfonyl esters, and acid amplifiers.

### Substrates and Features

The SRPs, and methods herein can be used with HAR features and related processes. For instance, wet processes such as etch and clean, which may make up greater than 25% of the overall process flow, can particularly challenging on HAR features due to the capillary forces that are generated during drying. The strength of these capillary forces can depend on the surface tension and contact angle of the etch, clean, or rinse fluids that are being dried, as well as the feature spacing and aspect ratio. If the forces generated during drying are too high, then the HAR features will collapse onto each other and stiction may occur. Feature collapse and stiction will severely degrade the device yield. Thus, in one aspect, the SRPs herein can be employed to reduce collapse of such structures.

In one example, a method for bracing HAR structures using an SRP includes providing HAR structures with a solvent. The substrate may be provided, for example, after a wet etch or cleaning operation and have solvent associated with the prior operation. In some embodiments, the solvent, i.e., to be disposed by the SRP, may be a transitional solvent if the prior solvent is not chemically compatible with the SRP solution.

The SRP can be disposed on any useful substrate or surface. The surface may be a planar surface or include one or more pillars, holes, gaps, and trenches, including HAR structures. Yet other surfaces can include those on devices, such as electronic components, printed circuit boards, packages, and others. Examples of substrate surfaces include silicon, silicon germanium, and germanium structures such as fins and nanowires, metal surfaces including but not limited to copper, cobalt, titanium, titanium nitride, tungsten or molybdenum, and/or other structures and materials.

### Apparatus

The removal processes described may be implemented in a chamber which may be part of a substrate processing system. The substrate processing system may further include one or more additional substrate processing tools used to process substrates including deposition of SRPs and upstream and downstream processing. Referring now to FIG. 4, a substrate processing system 400 includes one or more substrate processing tools 402 (substrate processing tools 402a and 402b are shown for illustration purposes) and substrate buffer 430 or other substrate storage. Each of the substrate processing tools 402a and 402b includes a plurality of processing chambers 404a, 404b, 404c, etc. (collectively processing chambers 404). For example only, each of the processing chambers 404 may be configured to perform a substrate treatment. In some examples, the substrates may be loaded into one of the processing chambers 404, processed, and then moved to one or more other ones of the processing chambers 404 and/or removed from the substrate processing tool 400 (e.g., if all perform the same treatment).

Substrates to be processed are loaded into the substrate processing tools 402a and 402b via ports of a loading station of an atmosphere-to-vacuum (ATV) transfer module 408. In some examples, the ATV transfer module 408 includes an equipment front end module (EFEM). The substrates are then transferred into one or more of the processing chambers 404. For example, a transfer robot 412 is arranged to transfer substrates from loading stations 416 to load locks 420. A vacuum transfer robot 424 of a vacuum transfer module 428 is arranged to transfer substrates from the load locks 420 to the various processing chambers 404.

After processing in one or more of the substrate processing tools 402a and 402b, the substrates may be transported outside of a vacuum environment. For example, the substrates may be moved to a location for storage (such as the substrate buffer 430). In other examples, the substrates may be moved directly from the substrate processing tool to another substrate processing tool for further processing or from the storage buffer 430 to another substrate processing tool for further processing.

Exposure of the substrate to ambient conditions may cause defects or otherwise adversely impact downstream processing. A sacrificial protective layer including an SRP can be added to the substrate prior to exposure to ambient conditions. In some examples, the sacrificial protective layer is applied in the substrate processing tool prior to transferring the substrate to the substrate buffer for storage or to another substrate processing tool. In other examples, the sacrificial protective layer is applied in another processing chamber (not associated with the substrate processing tool).

Prior to performing another treatment on the substrate, the sacrificial protective layer is removed as described herein. For example, the substrate may be transferred to the substrate processing tool 402b after a period of storage in the storage buffer 430 or after processing in the substrate processing tool 402a. The sacrificial protective layer may be removed in one of the processing chambers in the substrate processing tool 402b, or another processing chamber (not associated with the substrate processing tool 402b). In some embodiments, the sacrificial protective layer is removed in a load lock 420.

In some examples, the sacrificial protective layer is applied by a processing chamber in the same substrate processing tool (that performed substrate treatment) prior to exposure to ambient conditions. Since the substrate processing tool operates at vacuum, exposure of the substrate to ambient conditions is prevented. In some examples, the sacrificial layer is deposited after a wet clean process. In this case, oxides and residues may be removed by the wet clean process and the sacrificial layer is deposited in sequence prior to drying the wafer or immediately after drying the wafer. In some examples, this process is not done under vacuum and is done without any exposure of the dry pristine surface to the ambient. In other examples, the substrate is transported from the substrate processing tool to another processing chamber located outside of the substrate processing tool that adds the sacrificial protective layer. Using this approach limits or reduces the period of exposure of the substrate to ambient conditions. Exposure is limited to a brief period of transport from the substrate processing tool to the processing chamber where the sacrificial protective layer is applied. Storage of the substrate may be performed for longer periods without additional exposure to ambient conditions. Subsequently, the sacrificial protective layer may be removed prior to further processing. In some examples, the sacrificial protective layer is removed in another substrate processing tool under vacuum conditions prior to substrate treatment in processing chambers of the same substrate processing tool. In other examples, the substrate is transported to a processing chamber that removes the sacrificial protective layer and then to the substrate processing tool for further processing. This approach also limits exposure to ambient conditions between the processing chamber and the substrate processing tool or other environment. In one example, the sacrificial protective layer is formed immediately after etch, deposition, or other process by exposing the substrate to a small molecule vapor that condenses on the surface to form a film. This can be performed directly inside the tool in which the etch or deposition occurred (e.g., substrate processing tool 402a) and may occur in the same processing chamber in which the etch or deposition occurred. The substrate is then taken to the next tool for processing (e.g., substrate processing tool 402b). Once the substrate is again no longer exposed to ambient conditions (for example by bringing the substrate under vacuum or an atmosphere purged with an inert gas), vacuum and compounds, and in some cases, other stimuli, as described above are applied to induce the film to degrade and be removed from the substrate. This may take place inside of a processing chamber as described above (e.g., process chamber 404a of substrate processing chamber 402b).

In various embodiments, a system controller is employed to control process conditions during processing including during the SRP removal. The controller will typically include one or more memory devices and one or more processors. A processor may include a CPU or computer, analog and/or digital input/output connections, stepper motor controller boards, etc.

The controller may control all the activities of a removal apparatus. The system controller executes system control software, including sets of instructions for controlling the timing, mixture of gases, chamber pressure, chamber temperature, wafer temperature, wafer chuck or pedestal position, plasma power, and other parameters of a particular process. Other computer programs stored on memory devices associated with the controller may be employed in some embodiments.

Typically, there will be a user interface associated with the controller. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the reactant pulses and purge gas flows and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, substrate temperature, and plasma power. These parameters are provided to the user in the form of a recipe and may be entered utilizing the user interface.

Signals for monitoring the process may be provided by analog and/or digital input connections of the system controller. The signals for controlling the process are output on the analog and digital output connections of the system.

The system software may be designed or configured in many ways.

For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. The parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck. A plasma power program may control plasma power.

Examples of chamber sensors that may be monitored during removal include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically comprises some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### Conclusion

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
depositing a stimulus responsive polymer (SRP) on a substrate, wherein the SRP comprises a homopolymer, and wherein the homopolymer comprises a molecular weight of from about 250 g/mol to about 1500 kg/mol and a ceiling temperature less than about 300° C., thereby forming a film on a surface of the substrate.

2. The method of claim 1, wherein said depositing comprises depositing a formulation comprising the SRP, and wherein the formulation comprises a solvent, a plasticizer, an organic acid having a pKa more than or equal to 1, a photoacid generator, a thermal acid generator, and/or a dye.

3. The method of claim 1, wherein the molecular weight of the homopolymer is a weight-average molecular weight of from about 500 g/mol to 1000 kg/mol.

4. The method of claim 1, wherein the ceiling temperature is less than about 60° C., less than about 50° C., less than about 40° C., less than about 30° C., or lower.

5. The method of claim 1, further comprising, after said depositing:
storing the film in an ambient condition, wherein the film provides protection for the surface of the substrate during storage; and
removing the film from the surface of the substrate.

6. The method of claim 5, wherein said removing comprises exposing the film to heat.

7. The method of claim 5, wherein said removing comprises exposing the film to a temperature ramping of from about 1° C./min to about 200° C./sec.

8. The method of claim 5, wherein said removing comprises exposing the film to an ultraviolet or vacuum ultraviolet light at a dosage of from about 0.1 mW/cm² to about 15 W/cm².

9. The method of claim 8, wherein said removing further comprises exposing the film at a temperature of from about 30° C. to about 700° C.

10. The method of claim 5, wherein said removing comprises exposing the film to metastable neutrals from a noble gas plasma.

11. The method of claim 5, wherein said removing comprises exposing the film to acidic or basic vapors at a temperature of from about 20° C. to about 200° C.

12. The method of claim 1, wherein the substrate comprises a trench or a gap.

13. The method of claim 12, wherein said depositing comprises filling the trench or the gap with the SRP.

14. The method of claim 1, wherein the substrate comprises a plurality of high aspect ratio structures with a first solvent.

15. The method of claim 14, wherein said depositing further comprises displacing the first solvent with a solution comprising the SRP.

16. The method of claim 1, wherein the homopolymer comprises a structure of one of formulas (I)-(XIII): 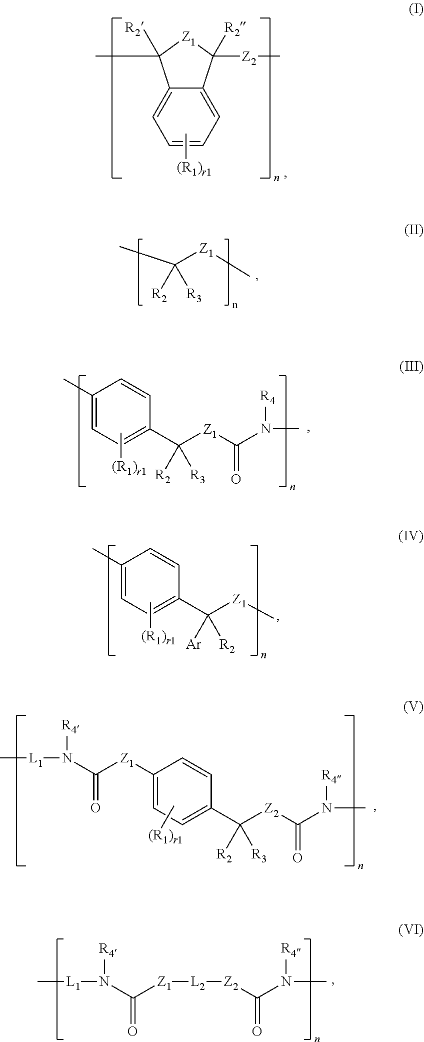 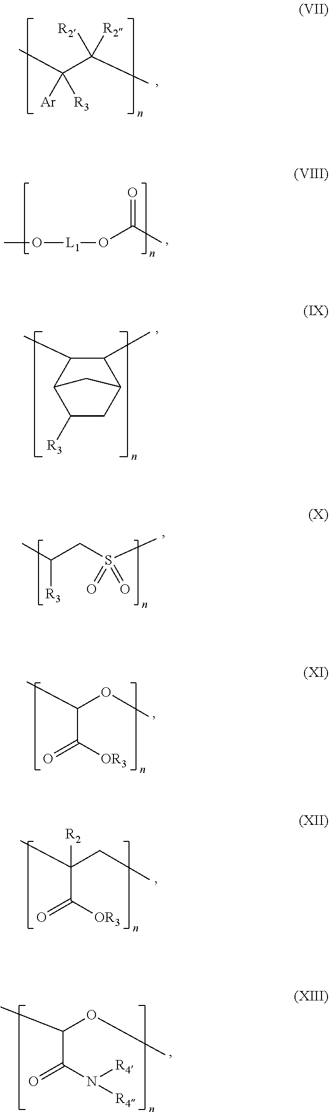
or a salt thereof, wherein:
each R₁ is, independently, H, optionally substituted alkyl, optionally substituted alkoxy, optionally substituted alkenyl, optionally substituted aryl, or halo;
each of R₂, R_{2′}, R_{2″}, and R₃ is, independently, H, optionally substituted alkyl, optionally substituted heteroalkyl, or optionally substituted aryl;
each of R₄, R_{4′}, and R_{4″} is, independently, H, optionally substituted alkyl, optionally substituted aminoalkyl, optionally substituted heteroalkyl, or R_{4′}, and R_{4″}, taken together with the nitrogen atom to which each are attached, form a heterocyclyl group, as defined herein;
Ar is optionally substituted aryl, optionally substituted alkyl, or optionally substituted aralkyl;
each of L₁ and L₂ is, independently, a covalent bond, optionally substituted alkylene, optionally substituted heteroalkylene, optionally substituted arylene, or optionally substituted cycloalkylene;
each of Z₁ and Z₂ is, independently, —O—, —S—, —CR₂R₃O—, —OCR₂R₃O—, —OCR₂R₃—, —CR₂R₃S—, —SCR₂R₃S—, or —SCR₂R₃—;
r1 is an integer from 1 to 4; and
n is from about 3 to about 100,000; and
wherein the homopolymer comprises a linear polymer or a cyclic polymer.

17. The method of claim 1, wherein the homopolymer comprises a structure of formula (Ia): 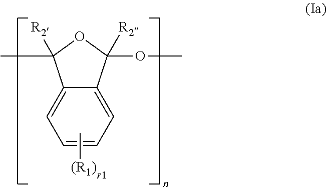
or a salt thereof, wherein:
each R₁ is, independently, H, optionally substituted alkyl, optionally substituted alkoxy, optionally substituted alkenyl, optionally substituted aryl, or halo;
each of R_{2′} and R_{2″} is, independently, H, optionally substituted alkyl, or optionally substituted aryl;
r1 is an integer from 1 to 4; and
n is from 4 to 100,000; and
wherein the homopolymer comprises a linear polymer or a cyclic polymer.

18. The method of claim 1, wherein the homopolymer comprises a structure of formula (Ib): 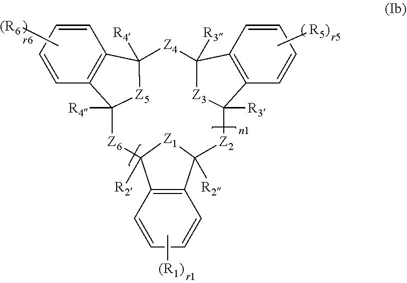
or a salt thereof, wherein:
each of R₁, R₅, and R₆ is, independently, H, optionally substituted alkyl, optionally substituted alkoxy, optionally substituted alkenyl, optionally substituted aryl, or halo;
each of R_{2′}, R_{2″}, R_{3′}, R_{3″}, R_{4′}, and R_{4″} is, independently, H, optionally substituted alkyl, or optionally substituted aryl;
each of Z₁, Z₂, Z₃, Z₄, Z₅, and Z₆ is, independently, —O—, —S—, —CR₂R₃O—, —OCR₂R₃O—, —OCR₂R₃—, —CR₂R₃S—, —SCR₂R₃S—, or —SCR₂R₃—, in which each of R₂ and R₃ is, independently, H, optionally substituted alkyl, or optionally substituted aryl;
each of r1, r5, and r6 is, independently, an integer from 1 to 4; and
n1 is from 1 to 100.

19. The method of claim 1, wherein the film comprises a protective film on a top surface or a bottom surface of the substrate.

20. The method of claim 13, further comprising, after said depositing:
removing a gapfill from the surface of the substrate.

21. The method of claim 15, further comprising, after said depositing:
drying the substrate to form a film comprising the SRP; and
removing the film from the substrate.

22. The method of claim 21, wherein said removing comprises exposing the substrate to a stimulus to remove the SRP.

23. The method of claim 22, wherein the stimulus comprises heat, ultraviolet light, metastable neutrals, acidic/basic chemistries, and/or plasma.

24. (canceled)

25. The method of claim 1, further comprising, prior to said depositing:
reacting a monomer in the presence of a reagent; and
terminating polymerization of the monomer to provide the SRP.

26. A structure comprising:
a semiconductor substrate having a top surface and a bottom surface; and
a layer of a stimulus responsive polymer (SRP) comprising a homopolymer, wherein the layer is disposed on the top surface and/or the bottom surface of the semiconductor substrate, and wherein the homopolymer comprises a molecular weight of from about 250 g/mol to about 1500 kg/mol and a ceiling temperature less than about 300° C.

27. The structure of claim 26, wherein the molecular weight of the homopolymer is of from about 500 g/mol to 1000 kg/mol.

28. The structure of claim 26, wherein the layer is configured to reduce permeation of one or more reactive airborne molecules to a surface of the substrate and/or to block one or more reactive sites disposed on a surface of the substrate.

29. The structure of claim 26, further comprising:
a plurality of high aspect ratio (HAR) structures disposed on the top surface of the substrate, wherein a gap is present between at least two of the HAR structures, wherein the layer substantially fills the gap.

30. The structure of claim 29, wherein the gap has an aspect ratio of from about 0.5:1 to about 300:1.

31. A formulation comprising:
about 0.1 wt. % to about 50 wt. % of a stimulus responsive polymer (SRP) comprising a homopolymer, wherein the homopolymer comprises a molecular weight of from about 250 g/mol to about 1500 kg/mol and a ceiling temperature less than about 300° C.; and
a solvent.

32. The formulation of claim 31, further comprising:
about 0.001 wt. % to about 25 wt. % of an additive selected from a plasticizer, an organic acid having a pKa more than or equal to 1, a photoacid generator, a thermal acid generator, and/or a dye.

33. A substrate processing tool configured to deposit a stimulus responsive polymer on a substrate.

34. The substrate processing tool of claim 33, wherein the stimulus responsive polymer is a homopolymer.
